(19) United States
(12) Patent Application Publication
(10) Pub. No.: US 2025/0338758 A1
(43) Pub. Date: Oct. 30, 2025

(54) DISPLAY DEVICE AND ELECTRONIC APPARATUS

(71) Applicant: Sony Semiconductor Solutions Corporation, Kanagawa (JP)

(72) Inventors: Akitsuna Takagi, Kanagawa (JP); Naoto Oda, Kanagawa (JP)

(21) Appl. No.: 18/870,100

(22) PCT Filed: Jun. 13, 2023
(86) PCT No.: PCT/JP23/21876

§ 371 Date: Nov. 27, 2024

(30) Foreign Application Priority Data
Jul. 12, 2022 (JP) 2022-112038

(51) Int. Cl. H10K 59/80; H10K 59/38; H10K 59/82

(52) U.S. Cl. CPC H10K 59/874; H10K 59/38; H10K 59/80522; H10K 59/82; H10K 59/8792

(57) ABSTRACT

Display devices with suppressed moisture entry into the display area are disclosed. In one example, a display device includes a light emitting element substrate in which an inorganic insulating layer and a light emitting element are formed in this order on a substrate, and a protective layer that covers an upper surface side of the light emitting element substrate. The protective layer is provided with a planarizing layer and a functional layer different from the planarizing layer on an upper side of the protective layer. The inorganic insulating layer has at least one of a groove or a step. The protective layer includes a covering portion that covers at least a part of the groove or the step.

### TECHNICAL FIELD

The present disclosure relates to a display device and an electronic apparatus.

### BACKGROUND ART

A display device using a light emitting element such as an organic EL element is required to suppress moisture entry into a light emitting element provided in a display area. As a moisture entry path, a path passing through a protective layer provided on the substrate is pointed out. Patent Document 1 discloses a technique of extending a moisture entry path of a passivation film serving as a protective layer provided on a substrate by directly providing a recess or a protrusion on the substrate so as to surround a display panel.

### CITATION LIST

### Patent Document

Patent Document 1: Japanese Patent Application Laid-Open No. 2006-120635

### SUMMARY OF THE INVENTION

### Problems to be Solved by the Invention

In the technique of Patent Document 1, since irregularities are easily formed on the surface of the protective layer, there is room for improvement in improving the coating property and adhesion of a functional layer such as a color filter or a sealing substrate when the functional layer or the sealing substrate is provided on the upper side of the protective layer.

The present disclosure has been made in view of the above-described points, and an object of the present disclosure is to provide a display device and an electronic apparatus capable of suppressing moisture entry into a display area and improving coating property and adhesion of a functional layer or a sealing substrate in a case where the functional layer or the sealing substrate is provided above a protective layer.

### Solutions to Problems

The present disclosure is, for example, (1) a display device including:
a light emitting element substrate in which an inorganic insulating layer and a light emitting element are formed in this order on a substrate; and
a protective layer that covers an upper surface side of the light emitting element substrate, in which
the protective layer is provided with a planarizing layer and a functional layer different from the planarizing layer on an upper side of the protective layer,
the inorganic insulating layer has a groove or a step, and
the protective layer includes a covering portion that covers at least a part of the groove or the step.

The present disclosure may be (2) an electronic apparatus including the display device according to (1) described above.

### BRIEF DESCRIPTION OF DRAWINGS

FIG. 1A is a plan view for explaining one of examples of a display device. FIG. 1B is a partially enlarged plan view in which a part of a region XS surrounded by a broken line in FIG. 1A is enlarged. FIG. 1C is a cross-sectional view schematically illustrating a state of a longitudinal cross-section taken along line A-A of FIG. 1A.

FIG. 2 is a cross-sectional view for explaining an example of the display device according to a first embodiment.

FIGS. 3A, 3B, 3C, and 3D are cross-sectional views illustrating an example of the manufacturing method of the display device.

FIGS. 4A and 4B are cross-sectional views illustrating an example of the manufacturing method of a display device.

FIG. 5 is a cross-sectional view for explaining an example of a display device according to a modification of the first embodiment.

FIG. 6 is a plan view for explaining an example of a display device according to the first embodiment.

FIG. 7 is a cross-sectional view for explaining an example of a display device according to a second embodiment.

FIG. 8 is a cross-sectional view for explaining an example of a display device according to a third embodiment.

FIG. 9 is a cross-sectional view for explaining an example of a display device according to a fourth embodiment.

FIG. 10 is a cross-sectional view for explaining an example of a display device according to a fifth embodiment.

FIG. 11 is a plan view of a display device according to a sixth embodiment.

FIG. 12 is a cross-sectional view for explaining an example of the display device according to the sixth embodiment.

FIG. 13 is a cross-sectional view for explaining an example of a display device according to a seventh embodiment.

FIG. 14 is a cross-sectional view for explaining an example of a display device according to an eighth embodiment.

FIG. 15 is a cross-sectional view for explaining an example of a display device according to a ninth embodiment.

FIG. 16 is a cross-sectional view for explaining an example of a display device according to a tenth embodiment.

FIG. 17 is a cross-sectional view for explaining an example of a display device according to an eleventh embodiment.

FIGS. 18A and 18B are diagrams for explaining examples of a display device having resonator structures.

FIGS. 19A and 19B are diagrams for explaining examples of a display device having resonator structures.

FIGS. 20A and 20B are diagrams for explaining examples of a display device having resonator structures.

FIG. 21 is a diagram for explaining an example of a display device having resonator structures.

FIGS. 22A, 22B, and 22C are diagrams for explaining examples in a case where the display device includes a wavelength selection unit.

FIG. 23 is a diagram for explaining an example in a case where the display device includes the wavelength selection unit.

FIGS. 24A and 24B are diagrams for explaining examples in a case where the display device includes the wavelength selection unit.

FIG. 25 is a diagram for explaining an example in a case where the display device includes the wavelength selection unit.

FIGS. 26A and 26B are diagrams for explaining an application example of a display device.

FIG. 27 is a diagram for explaining an application example of the display device.

FIG. 28 is a diagram for explaining an application example of the display device.

FIG. 29 is a diagram for explaining an application example of the display device.

FIG. 30 is a diagram for explaining an application example of the display device.

FIGS. 31A and 31B are diagrams for explaining application examples of the display device.

### MODE FOR CARRYING OUT THE INVENTION

Hereinafter, an example and the like according to the present disclosure will be described with reference to the drawings. Note that explanation will be made in the following order. In the present specification and the drawings, configurations having substantially the same functional configuration are denoted by the same reference signs, and redundant descriptions are omitted.

Note that the description will be given in the following order.

1. First Embodiment

2. Second Embodiment

3. Third Embodiment

4. Fourth Embodiment

5. Fifth Embodiment

6. Sixth Embodiment

7. Seventh Embodiment

8. Eighth Embodiment

9. Ninth Embodiment

10. Tenth Embodiment

11. Eleventh Embodiment

12. Example cases where a display device has resonator structures

13. Examples of positional relationship in cases where a display device includes wavelength selection units

14. Application example

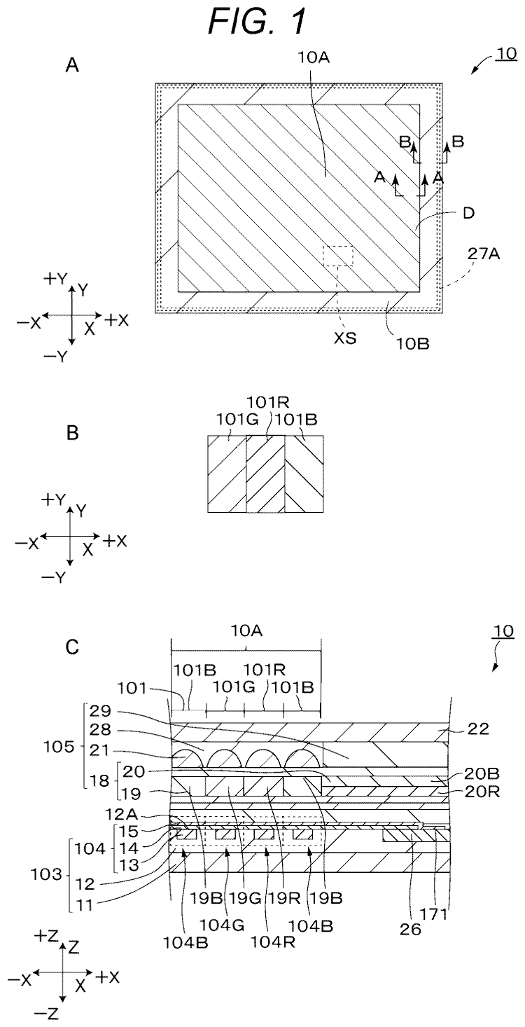

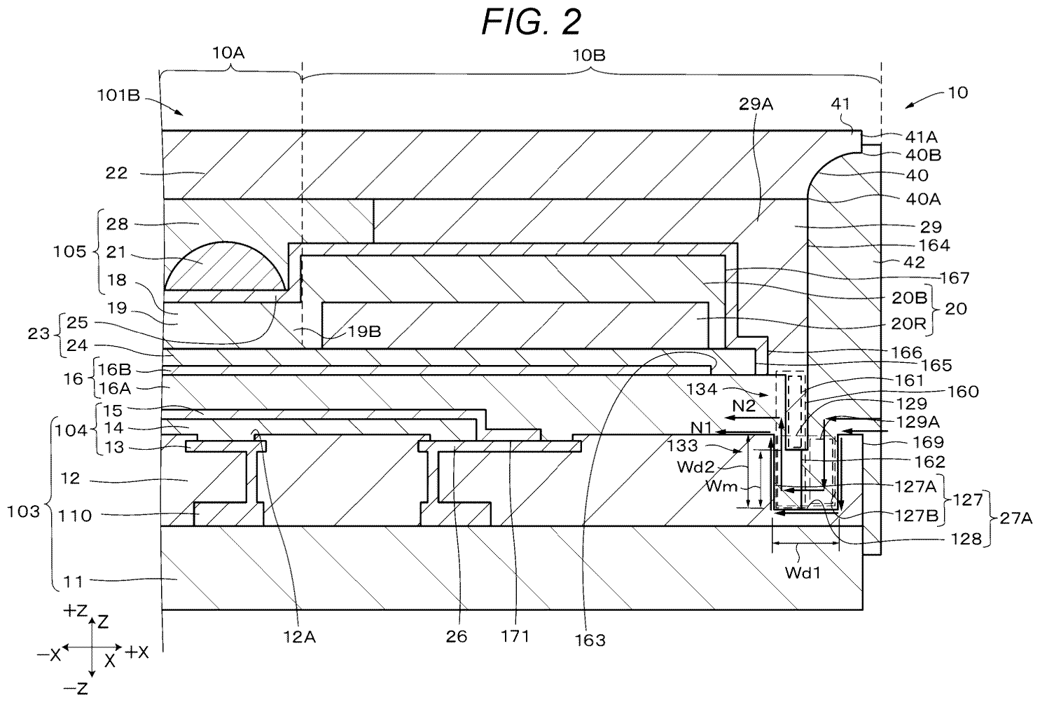

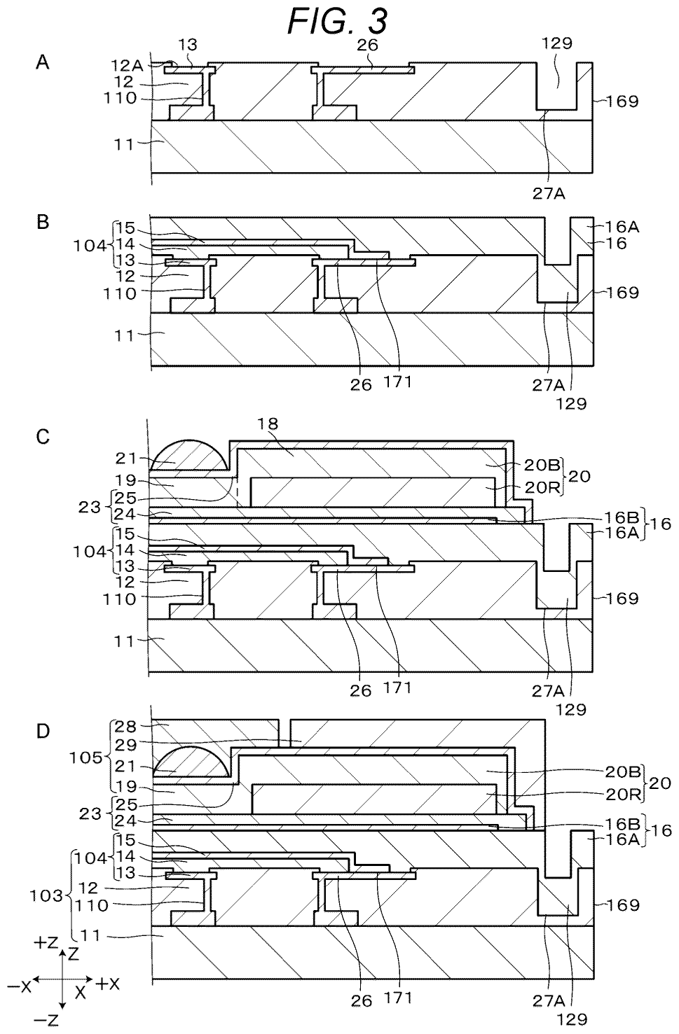

The following description is preferred specific examples of the present disclosure, and the content of the present disclosure is not limited to these embodiments and the like. Furthermore, in the following description, directions such as forward and backward, rightward and leftward, and upward and downward directions are used for ease of explanation, but the contents of the present disclosure are not limited by these directions. In examples of FIGS. 1A, 1B, 1C, and FIG. 2, a Z-axis direction is defined as an up-down direction (an upper side is in a +Z direction, and a lower side is in a −Z direction), an X-axis direction is defined as a front-back direction (a front side is in a +X direction, and a back side is in a −X direction), and a Y-axis direction is defined as a left-right direction (a right side is in a +Y direction, and a left side is in a −Y direction), and the description will be made on the basis of this. The similarity applies in FIGS. 3 to 21. A relative dimensional ratio of the size and thickness of each layer illustrated in each drawing of FIG. 1A and others is shown for convenience, and does not limit any actual dimensional ratios. This similarity applies to the drawings of FIGS. 1B and 1C and FIGS. 2 to 17 regarding the definition and the dimensional ratio regarding these directions.

### 1 First Embodiment

### [1-1 Configuration]

Examples of a display device according to an embodiment of the present disclosure include an organic electroluminescence (EL) display device. In the display device according to the first embodiment, as illustrated in FIGS. 1A, 1B and 1C, a case where the display device is an organic EL display device (hereinafter, simply referred to as a “display device 10”) will be described as an example. FIG. 1A is a plan view illustrating an example of the display device 10. FIG. 1B is a diagram for schematically explaining a layout of sub-pixels in a portion of region XS in FIG. 1A. FIG. 1C is a cross-sectional view schematically illustrating a state of a longitudinal cross-section taken along line A-A of FIG. 1A.

### (Display Area and Outer Area)

In the display device 10, a display area 10A and an outer area 10B are defined on a display surface D side. The display area 10A is a region determined as a region where light generated by a plurality of light emitting elements 104 is emitted. The outer area 10B is determined as a region outside the outer peripheral edge of the display area 10A. In the example of FIG. 1A, the display area 10A is formed as a rectangular region. A region defined as a rectangular annular region outside the display area 10A is the outer area 10B. A position of an outer edge of the display area 10A is a position of an inner peripheral edge of the outer area 10B, and the display area 10A and the outer area 10B are in contact with each other at boundaries. Note that the display surface D illustrated in FIG. 1A indicates a surface on which light generated from the light emitting element 104 is extracted to the outside in the display device 10.

In the description below, a case where the display device 10 performs display by a top emission method is explained as an example. The top emission method indicates a method by which the light emitting elements 104 are disposed on the side of the light emitting surface rather than the side of a substrate 11. Accordingly, in the display device 10, the substrate 11 is located on the back surface side of the display device 10, and the direction (+Z direction) from the substrate 11 toward the light emitting elements 104 described later is the direction toward the front surface side (upper surface side) of the display device 10. In the display device 10, light generated from the light emitting elements 104 is directed in the +Z direction, and is emitted to the outside. In the description below, in each of the layers constituting the display device 10, the surface on the display surface side in the display area (display area 10A) of the display device 10 will be referred to as the first surface (upper surface), and the surface on the back surface side of the display device 10 will be referred to as the second surface (lower surface). Note that this does not prohibit the case where the display device 10 according to the present disclosure is of a bottom emission method. The display device 10 is also applicable to a bottom emission method. By a bottom emission method, light generated from the light emitting elements 104 is directed in the −z direction, and is emitted to the outside.

### (Type of Sub-Pixel)

In the examples of FIGS. 1A, 1B, 1C, and the like, three colors of red, green, and blue are determined as a plurality of color types corresponding to a plurality of emission colors of the display device 10, and three types of a sub-pixel 101R, a sub-pixel 101G, and a sub-pixel 101B are provided as the sub-pixels. The sub-pixel 101R, the sub-pixel 101G, and the sub-pixel 101B are a red sub-pixel, a green sub-pixel, and a blue sub-pixel, respectively, and display the red color, the green color, and the blue color, respectively. However, the example of FIG. 1 is an example, and the display device 10 is not limited to the case of including the plurality of sub-pixels corresponding to three color types. Furthermore, wavelengths of light corresponding to the respective color types of red, green, and blue can be determined as, for example, wavelengths in a range of 610 nm to 650 nm (red wavelength band), a range of 510 nm to 590 nm (green wavelength band), and a range of 440 nm to 480 nm (blue wavelength band), respectively. Note that the number of color types of the sub-pixels is not limited to the three colors illustrated here, and may be two colors, four colors, or the like. Furthermore, the color type of the sub-pixels is not limited to red, green, and blue, and may be yellow, white, or the like.

Furthermore, the layout of the sub-pixels 101B, 101R, and 101G in the display device 10 is not particularly limited, but in the example of FIG. 1, in a predetermined region constituting the display surface, the sub-pixels 101B, 101R, and 101G constituting one pixel are arranged in a stripe shape, and each pixel is two-dimensionally provided. Therefore, in the display device 10 illustrated in the example of FIG. 1, the plurality of sub-pixels 101B, 101R, and 101G corresponding to the plurality of color types is provided in a two-dimensional and stripe-shaped layout. Note that FIG. 1B is an example, and as will be described later, the layout of the sub-pixels 101B, 101R, and 101G is not limited in the present disclosure. The example of FIG. 1A is a diagram for explaining the display area 10A of the display device 10.

In the description of the present specification, in a case where the types of the sub-pixels 101R, 101G, and 101B are not particularly distinguished, the sub-pixels 101R, 101G, and 101B are collectively referred to as the sub-pixel 101.

### (Drive of Sub-Pixel)

The display device 10 generally includes a control circuit (not illustrated), an H driver, and a V driver (not illustrated), and the control circuit controls driving of the H driver and the V driver. The H driver and the V driver control driving of the sub-pixels 101 in units of columns and rows, respectively, in a case where a two-dimensional matrix is allocated to each sub-pixel 101.

### (Light Emitting Element Substrate)

In the example of FIG. 1C, the display device 10 includes a light emitting element substrate 103. In the light emitting element substrate 103, an inorganic insulating layer 12 and a light emitting element 104 are formed on the substrate 11. Here, as described later, the light emitting element 104 has a structure in which a first electrode 13, an organic layer 14, and a second electrode 15 are laminated in this order.

### (Substrate)

The substrate 11 may include glass or resin having low moisture and oxygen permeability, or may contain a semiconductor in which transistors and the like are easily formed, for example. Specifically, the substrate 11 may be a glass substrate, a semiconductor substrate, a resin substrate, or the like.

As illustrated in FIGS. 1C and 2, the inorganic insulating layer 12 is provided on the substrate 11, and various circuits for driving the plurality of light emitting elements 104 are provided in the inorganic insulating layer 12. Examples of the various circuits include a drive circuit that controls driving of the light emitting elements 104, and a power supply circuit that supplies power to the plurality of light emitting elements 104 (none of which is shown in the drawings). The various circuits are restricted from being exposed to the outside by the inorganic insulating layer 12. Furthermore, the substrate 11 is provided with a wiring 110 for connecting the light emitting elements 104, a circuit provided on the substrate 11, and the like to the first electrode 13 and the like. Examples of the wiring 110 include a plurality of contact plugs.

### (Inorganic Insulating Layer)

The inorganic insulating layer 12 includes an organic material or an inorganic material, for example. The organic material contains at least one material of polyimide or acrylic resin, for example. The inorganic material contains at least one material of silicon oxide, silicon nitride, silicon oxynitride, or aluminum oxide, for example.

### (Groove or Step)

The inorganic insulating layer 12 has a groove or a step. The groove or the step forms a height difference portion (a portion forming a difference in position in the height direction) (in FIG. 2, a first height difference portion 133). As illustrated in FIGS. 1A and 2, in a case where the thickness direction (Z-axis direction) of the light emitting element substrate 103 is a line-of-sight direction, the inorganic insulating layer 12 has a groove or a step at a position corresponding to the outer area 10B. In the example of FIG. 2, the inorganic insulating layer has a groove 27A. The layout of the groove 27A is not particularly limited, but the groove 27A is preferably formed in an annular shape so as to surround the display area 10A. In the examples of FIGS. 1A and 2, the groove 27A is formed in a rectangular annular shape.

### (Groove)

As described above, the groove 27A is formed at a position outside the display area 10A in a case where the thickness direction (Z-axis direction) of the light emitting element substrate 103 is a line-of-sight direction (in plan view of the display device 10). Furthermore, the groove 27A has a wall portion 127 and a bottom surface 128, and is preferably formed at a lower position of an end portion 41 of a sealing substrate 22 or a predetermined position closer to the display area 10A side (−X direction side in FIG. 2) than the lower position thereof. In a case where the Z-axis direction is a line-of-sight direction, at least a part of the bottom surface 128 of the groove 27A is preferably formed in a region corresponding to a portion between an end surface 41A of the end portion 41 of the sealing substrate 22 (a distal end 40B of an inclined portion 40) and a proximal end 40A of the inclined portion 40 described later in a plan view of the display device 10. In this case, at the time of manufacturing the display device 10, as illustrated in FIG. 2, it is easy to form a covering portion 160 so as to be in contact with the wall portion 127 of the groove 27A and cover a first wall portion 127A, and fill a portion 129A of an in-groove space 129 excluding the covering portion 160 with an end surface coating portion 42 or the like. Note that the in-groove space 129 indicates a space portion surrounded by the wall portion 127 (the first wall portion 127A and the second wall portion 127B) and the bottom surface 128 of the groove 27A.

In the example of FIG. 1A, the groove 27A is formed in a rectangular annular shape, but this is an example, and the groove is not limited to a rectangular annular shape, and may be an annular shape, an elliptical annular shape, or the like.

### (Cross-Sectional Shape of Groove)

The cross-sectional shape of the groove 27A is not particularly limited, and may be a non-tapered shape as in the example of FIG. 2, a tapered shape, or a reverse tapered shape.

### (Width of Groove)

The width of the groove 27A is not particularly limited as long as it is at least a size that allows formation of a height difference structure (second height difference portion 134 in FIG. 2) corresponding to the groove 27A on the upper surface side of the covering portion 160 of a protective layer 16 in a case where the protective layer 16 to be described later is formed on the inorganic insulating layer 12. The height difference structure to be the second height difference portion 134 can be exemplified by a recessed structure or a stepped structure. Furthermore, when the height difference structure to be the second height difference portion 134 is formed, it is possible to extend the moisture entry path along the inside of the protective layer 16. From the viewpoint of forming the height difference structure, the width of the groove 27A is preferably larger than the thickness of the protective layer 16. In particular, in the example of FIG. 2, since a part of the wall portion 127 and the bottom surface 128 of the groove 27A is in contact with a first protective layer 16A and covers the wall portion 127 and the bottom surface 128, a width Wd1 of the groove 27A is preferably larger than a thickness Wm of the first protective layer 16A.

### (Depth of Groove)

The depth of the groove 27A is set such that, in a case where the protective layer 16 described later is formed on the inorganic insulating layer 12, a height difference structure corresponding to the groove 27A can be formed on the upper surface side of the covering portion 160 of the protective layer 16. From this viewpoint, the depth of the groove 27A is preferably larger than the thickness of the protective layer 16. In particular, in the example of FIG. 2, since a part of the bottom surface 128 of the groove 27A is in contact with the first protective layer 16A and covers the bottom surface 128, a depth Wd2 of the groove 27A is preferably larger than the thickness Wm of the first protective layer 16A.

### (Number of Grooves or Steps)

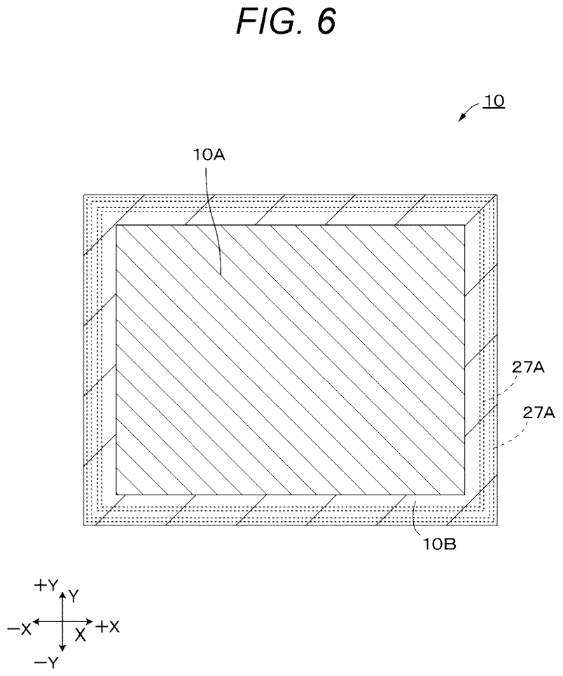

In the example of FIG. 2 and the like, one groove 27A is formed as a groove or a step, but two or more grooves or steps may be provided. For example, as illustrated in FIG. 6, a plurality of grooves 27A may be annularly formed in the outer area 10B so as to surround the display area 10A. FIG. 6 is a plan view for explaining an example in a case where a plurality of grooves or steps is formed. In a case where two or more grooves 27A are formed in the inward and outward directions as illustrated in FIG. 6, the position of the groove 27A is not particularly limited as long as it is the outer area 10B. For example, the groove 27A is formed such that the proximal end 40A of the inclined portion 40 is positioned on the bottom surface 128 of the outermost groove 27A, and the groove 27A on the inner side of the outermost groove 27A is formed at a predetermined position closer to the display area 10A side than the proximal end 40A of the inclined portion 40 in the outer area 10B. Furthermore, the combination of the groove or the step may be a combination of the groove 27A and a step 27B as described in a modification of the first embodiment described later so as to surround the display area 10A.

### (Light Emitting Element)

A plurality of light emitting elements 104 is disposed on the first surface of the inorganic insulating layer 12. In the examples in FIGS. 1, 2, and others, the light emitting elements 104 are organic electroluminescence elements (organic EL elements). As the plurality of light emitting elements 104, light emitting elements that set a color corresponding to the color type of the sub-pixel 101 as light emitted (as an emission color) from a light emitting surface are provided. For example, light emitting elements 104R, 104G, and 104B are formed in the sub-pixels 101R, 101G, and 101B, respectively. Furthermore, the plurality of light emitting elements 104 is arranged in a layout corresponding to the arrangement of the sub-pixels 101 of the respective color types. Note that, in the present specification, in a case where the types such as the light emitting elements 104R, 104G, and 104B are not particularly distinguished, the term light emitting element 104 is used.

Each of the light emitting elements 104 has a multilayer structure in which the first electrode 13, the organic layer 14, and the second electrode 15 are layered in this order. The first electrode 13, the organic layer 14, and the second electrode 15 are layered in this order from a side of the substrate 11 in a direction (+Z direction) from the second surface toward the first surface.

### (First Electrode)

A plurality of the first electrodes 13 is provided on the first surface side of the substrate 11. In the example in FIG. 2, the first electrodes 13 are anode electrodes.

The first electrodes 13 each include at least one of a metal layer or a metal oxide layer. The first electrodes 13 may each include a single-layer film of a metal layer or a metal oxide layer, or a multilayer film of a metal layer and a metal oxide layer.

The metal layer contains at least one metal element selected from the group consisting of chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag), for example. The metal layer may contain the at least one metal element described above as a constituent element of an alloy. Specific examples of the alloy include an aluminum alloy and a silver alloy. Specific examples of the aluminum alloy include AlNd and AlCu, for example.

The metal oxide layer contains at least one of a mixture of indium oxide and tin oxide (ITO), a mixture of indium oxide and zinc oxide (IZO), or titanium oxide (TiO), for example.

In FIGS. 1C and 2, the first electrodes 13 are electrically separated for the respective sub-pixels 101. That is, a plurality of the first electrodes 13 is provided on the first surface side of the substrate 11, and is provided for every sub-pixel 101.

Furthermore, a layer having insulating properties is preferably formed between adjacent first electrodes 13. In the examples in FIGS. 1C and 2, the inorganic insulating layer 12 is formed between adjacent first electrodes 13. In the examples in FIGS. 1C, 2, and others, the inorganic insulating layer 12 electrically separates each first electrode 13 for each light emitting element 104 (that is, for each sub-pixel 101).

Furthermore, as illustrated in FIG. 1C, openings 12A are formed in the inorganic insulating layer 12 on the first surface side, the first surfaces of the first electrodes 13 (the surfaces facing the second electrode 15) are exposed through the openings 12A of the inorganic insulating layer 12, and the portions of the first electrodes 13 exposed through the openings 12A face the organic layer 14 described later while avoiding interposition of the inorganic insulating layer 12. Note that the inorganic insulating layer 12 may be formed not only between the adjacent first electrodes 13, but also onto the edge portions of the first electrodes 13. The edge portion of each first electrode 13 is defined by a portion from the outer peripheral edge of the first electrode 13 to a predetermined position closer to the center side of the first electrode 13. In this case, the inorganic insulating layer 12 also has the openings 12A, and the first surfaces of the first electrodes 13 are exposed through the openings 12A.

### (Light Emitting Element)

In the display device 10, the plurality of light emitting elements 104 is provided on the upper side of the first surface of the substrate 11. In the example of FIG. 1C, as the plurality of light emitting elements 104, individual light emitting elements 104R, 104G, and 104B are formed to correspond to the individual sub-pixels 101R, 101G, and 101B. In the present specification, in a case where the types such as the light emitting elements 104R, 104G, and 104B are not particularly distinguished from each other, a term light emitting element 104 is used. The plurality of light emitting elements 104 is two-dimensionally arranged in a stripe-shaped arrangement pattern.

### (Organic Layer)

The organic layer 14 is an organic light emitting layer provided between the first electrode 13 and the second electrode 15. The organic layer 14 is provided as a layer common to the sub-pixels 101. In the example of FIG. 1C, the organic layer 14 is common to the sub-pixels 101R, 101G, and 101B, and is configured to be able to emit white light. However, this does not prohibit an emission color of the organic layer 14 from being other than white, and colors including red, blue, green, and the like may be adopted. That is, the emission color of the organic layer 14 may be, for example, any one of white, red, blue, or green.

The organic layer 14 has, for example, a configuration in which a hole injection layer, a hole transport layer, a light emitting layer, and an electron transport layer are laminated in this order from the first electrodes 13 toward the second electrode 15. An electron injection layer may be provided between the electron transport layer and the second electrode 15. The electron injection layer is for increasing electron injection efficiency. Note that the configuration of the organic layer 14 is not limited thereto, and layers other than the light emitting layer are provided as necessary.

The hole injection layer is a buffer layer for enhancing efficiency of hole injection into the light emitting layer and reducing leakage. The hole transport layer is for enhancing efficiency of hole transport to the light emitting layer. The electron transport layer is for enhancing efficiency of electron transport to the light emitting layer.

The light emitting layer generates light when recombination of electrons and holes is caused by an electric field. The light emitting layer is an organic compound layer containing an organic light-emitting material.

### (Second Electrode)

The second electrode 15 is provided on the upper side of the organic layer 14. A portion of the second electrode 15 corresponding to the sub-pixel 101 (a portion corresponding to the light emitting element 104) is provided so as to face the first electrode 13. The second electrode 15 is provided as an electrode common to the plurality of sub-pixels 101. The second electrode is formed in common in the plurality of sub-pixels. The second electrode 15 is a cathode electrode. The second electrode 15 is preferably a transparent electrode having transparency to light generated in the organic layer 14. The transparent electrode herein may be a transparent electrode including a transparent conductive layer, or a transparent electrode having a multilayer structure including a transparent conductive layer and a semi-transmissive reflective layer.

As the transparent conductive layer, a transparent conductive material having good optical transparency and a small work function is preferably used. The transparent conductive layer can include a metal oxide, for example. Specifically, examples of the material of the transparent conductive layer can include a material containing at least one of a mixture of indium oxide and tin oxide (ITO), a mixture of indium oxide and zinc oxide (IZO), or zinc oxide (ZnO).

The semi-transmissive reflective layer can include a metal layer, for example. Specifically, examples of the material of the semi-transmissive reflective layer can include a material containing at least one metal element selected from the group consisting of magnesium (Mg), aluminum (Al), silver (Ag), gold (Au), and copper (Cu). The metal layer may contain the at least one metal element described above as a constituent element of an alloy. Specific examples of the alloy include an MgAg alloy, an AgPdCu alloy, and the like.

### (Auxiliary Electrode)

In the display device 10, an auxiliary electrode 31 is provided in the outer area 10B. The auxiliary electrode 26 relays electrical connection between various circuits formed on the substrate 11 side and the second electrode 15.

The material of the auxiliary electrode 26 is not particularly limited as long as it is a conductive material, and for example, metal or the like can be used. As illustrated in FIG. 2, the second electrode 15 is extended from the display area 10A to the outside (outer area 10B) and connected to the auxiliary electrode 26, so that electrical connection between the second electrode 15 and the auxiliary electrode 26 can be achieved.

In the example of FIG. 2, the auxiliary electrode 26 is formed in a ring shape so as to surround a periphery of the display area 10A in plan view of the display area 10A. However, FIG. 2 is an example, and the layout of the auxiliary electrode 26 is not limited to a ring shape.

### (Protective Layer)

In the display device 10, it is preferable that the protective layer 16 is formed on the light emitting element substrate 103 so as to cover the formation surface side (first surface) of the light emitting element 104. The protective layer 16 makes it difficult for the first surface of the light emitting element 104 to come into contact with the outside air, and suppresses moisture entry into the light emitting element 104 from the external environment.

The protective layer 16 contains an insulating material. As the insulating material, thermosetting resin or the like can be used, for example. Other than that, the insulating material may be Sio, SiON, AlO, TiO, or the like. In this case, examples of the protective layer 16 include a CVD film containing SiO, SiON, or the like, and an ALD film containing AlO, Tio, Sio, or the like. Note that a CVD film means a film formed by chemical vapor deposition. An ALD film means a film formed by atomic layer deposition. The protective layer 16 may be formed as a single layer or may have a structure in which a plurality of layers is laminated. In the example of FIG. 2, the protective layer 16 has a multilayer structure of a first protective layer 16A and a second protective layer 16B. The first protective layer 16A and the second protective layer may be layers each containing a predetermined insulating material, or the first protective layer 16A and the second protective layer 16B may include a CVD film and an ALD film, respectively.

In a case where the protective layer 16 has a multilayer structure in which the first protective layer 16A and the second protective layer 16B are laminated in this order from the side closer to the first surface of the light emitting element substrate 103, the second protective layer 16B often has weaker adhesion to a seal layer 29 and the like described later. Therefore, it is preferable that the protective layer 16 is formed such that the contact area of the second protective layer 16B with the seal layer 29 is narrower than that of the first protective layer 16A. Specifically, in the example of FIG. 2, the first protective layer 16A is formed over a wide range in the display area 10A and the outer area 10B, and is in contact with the wall portion 127 of the groove 27A and covers the wall portion 127. An outer end surface 162 of the first protective layer 16A is covered with the end surface coating portion 42 described later. The second protective layer 16B is formed such that the position of an outer end surface 163 thereof is at a predetermined position on the display area 10A side (−X direction side in FIG. 2) with respect to the groove 27A. Note that in the example of FIG. 2, the outer end surface 163 of the second protective layer 16B is covered with a first planarizing layer 24 described later.

### (Covering Portion)

In the outer area 10B, in a case where the thickness direction of the light emitting element substrate 103 is a line-of-sight direction, the protective layer 16 has a covering portion 160. The covering portion 160 is a portion that covers at least a part of a surface (a wall portion or a bottom surface) of the groove or the step of the protective layer 16. Covering at least a part of the surface of the groove or the step includes not only a case of directly covering the groove or the step but also a case of indirectly covering the groove or the step via another layer.

In the example of FIG. 2, the covering portion 160 includes the first protective layer 16A of the protective layer 16. Furthermore, the covering portion 160 is in contact with the wall portion 127 of the groove 27A, covers the first wall portion 127A, and covers a part of the bottom surface 128 of the groove 27A. The covering portion 160 of the protective layer 16 has a recessed structure or a stepped structure on its upper surface side (first surface side), and in the example of FIG. 2, the stepped structure is formed on the upper surface side of the covering portion 160. Furthermore, the protective layer 16 forms an upper space 161 as a predetermined space on the upper surface side of the covering portion 160. The upper space 161 is a portion corresponding to a space on the upper surface side of the recessed structure or the stepped structure. In a case where the stepped structure is formed on the upper surface side of the covering portion 160, the upper space 161 indicates a space defined as a space outside the portion of the side wall portion of the stepped structure and above the portion of the bottom portion. In a case where the recessed structure is formed on the upper surface side of the covering portion 160, the upper space 161 indicates a space defined as a space surrounded by the inner surface of the recessed structure. The upper space 161 is formed immediately above the groove or the step (the groove 27A in the example of FIG. 2) of the inorganic insulating layer 12. Furthermore, a space (upper space 161) on the upper side of the covering portion 160 is filled with the seal layer 29, and an end surface 164 of the seal layer 29 is covered with the end surface coating portion 42.

### (Planarizing Layer and Functional Layer)

A planarizing layer 23 and a functional layer 105 are formed so as to cover the top (first surface) of the protective layer 16.

### (Planarizing Layer)

In the example of FIG. 2, a first planarizing layer 24 and a second planarizing layer 25 are formed as the planarizing layer 23. As illustrated in FIG. 2, the first planarizing layer 24 is formed on the protective layer 16. The first planarizing layer 24 may be a layer containing an inorganic material or a layer containing an organic material. As the inorganic material, a material similar to the material of the protective layer 16 can be exemplified. The organic material may be a resin material or the like, for example. The first planarizing layer 24 can improve the flatness of a surface for forming a color filter 18 described later. Furthermore, the first planarizing layer 24, together with the protective layer 16, makes the first surface of the light emitting element 104 less likely to come into contact with the outside air, and can suppress moisture entry into the light emitting element 104 from the external environment.

In the example of FIG. 2, the first planarizing layer 24 covers the second protective layer 16B, and is formed such that a position on the outer area 10B side with respect to the outer end surface 163 of the second protective layer 16B (position on the +X direction side in FIG. 2) and a predetermined position on the display area 10A side with respect to the groove 27A (position on the −X direction side in FIG. 2) is set as the position of an end surface 165. The end surface 165 of the first planarizing layer 24 is covered with the second planarizing layer 25 described later.

The second planarizing layer 25 is formed on the first surface of the color filter 18 described later. Similarly to the first planarizing layer 24, the second planarizing layer 25 may be a layer containing an inorganic material or a layer containing an organic material. The second planarizing layer 25 may contain the same material as that of the first planarizing layer 24, or may contain different materials.

### (Functional Layer)

On the first planarizing layer 24, the functional layer 105 is formed. The functional layer 105 is a layer structure excluding the planarizing layer 23 and indicates a layer structure formed on the upper side of the protective layer 16. Examples of the functional layer 105 include a color filter 18, a seal layer 29, a filling layer 28, and a lens 21.

### (Color Filter)

In the display device 10, the color filter 18 is provided on the first surface side (an upper side, the +Z direction side) of the first planarizing layer 24. As the color filter 18, an on chip color filter (OCCF) can be exemplified. As the color filter 18, a first color filter 19 and a second color filter 20 are provided. As a material of the color filter 18, an organic material can be exemplified.

### (First Color Filter)

The first color filter 19 is preferably formed substantially in the display area 10A. Furthermore, the first color filter 19 is provided according to a color type of the sub-pixel 101. Examples of the first color filter 19 include a red color filter (red filter 19R), a green color filter (green filter 19G), and a blue color filter (blue filter 19B) in the example of FIG. 1C. The red filter 19R, the green filter 19G, and the blue filter 19B are provided in the sub-pixels 101R, 101G, and 101B, respectively. Since the first color filter 19 is provided in the display device 10, light corresponding to the color type of the sub-pixels 101R, 101G, and 101B can be effectively extracted to the outside.

### (Second Color Filter)

The second color filter 20 is formed outside the first color filter 19 provided on the outermost side. In FIG. 2, the second color filter 20 is formed substantially in the outer area 10B. The second color filter 20 is formed so as to cover an upper side (+Z direction side) of the auxiliary electrode 26. The second color filter 20 functions as a layer having a light shielding property. The second color filter 20 has a structure in which a red color filter (red filter 20R) and a blue color filter (blue filter 20B) are laminated. The red filter 20R may be formed simultaneously with the red filter 19R by using a similar material. The blue filter 20B may be integrally formed simultaneously with the blue filter 19B by using a similar material.

The red filter 20R can be exemplified by, for example, a filter that easily allows light of a red wavelength band among visible light to pass through, and easily absorbs light of other color wavelength bands. The blue filter 20B can be exemplified by a filter that easily allows light of a blue wavelength band among visible light to pass through, and easily absorbs light of other color wavelength bands. According to such a structure in which the red filter 20R and the blue filter 20B are laminated, light blocking can be achieved for light in wavelength bands of a wide range. Therefore, among light generated by the light emitting element 104 in the display area 10A, light traveling obliquely from the outer area 10B to the outside is substantially suppressed from passing through the second color filter 20. Thus, an effect of suppressing light leakage by the second color filter 20 is exhibited. Light traveling from the outside of the display device 10 toward the substrate 11 side is blocked by the second color filter 20, and entry of external light is suppressed.

As described above, the second color filter 20 has a light shielding property in a state where the red filter 20R and the blue filter 20B are laminated, and the multilayer structure of the red filter 20R and the blue filter 20B functions as a light shielding filter. Note that, in the example illustrated in FIG. 2A, an innermost end of the second color filter 20 is in contact with an outermost end of the first color filter 19.

The position of an end surface 167 at the outer end of the second color filter 20 is a predetermined position closer to the display area 10A side than the groove 27A, and the end surface 167 at the outer end of the second color filter 20 is covered with the second planarizing layer 25.

### (Seal Layer)

A seal layer 29 is formed on the color filter 18. The seal layer 29 is preferably formed in a region that covers at least a part of the second color filter 20 with the thickness direction of the light emitting element substrate 103 as the line-of-sight direction (in plan view of the light emitting element substrate 103), and is preferably formed so as to substantially cover the region of the outer area 10B. In the example of FIG. 2, the seal layer 29 is formed so as to cover the second planarizing layer 25. Furthermore, the seal layer 29 is formed so as to fill at least a part of the upper space 161 formed on the upper side of the covering portion 160 covering the space (in-groove space 129) in the groove 27A. In the example of FIG. 2, the upper space 161 is filled with the seal layer 29, and the end surface coating portion 42 covers the end surface 164 of the seal layer 29. The seal layer 29 is formed by a seal material. A seal material 29A is preferably a transparent adhesive layer. As a material of the seal layer 29 (a material of the seal material 29A), a resin material or the like may be used. The material of the seal layer 29 is not particularly limited, but a material having higher moisture resistance than the color filter 18 is suitably used. A hygroscopic material may be added to the seal layer 29.

### (Lens)

The functional layer 105 may have the lens 21. The lens 21 is preferably formed on the first color filter 19 (on the first surface). In the example of FIG. 1, the lens 21 is provided in a layout corresponding to each sub-pixel 101. The lens 21 is preferably an on chip lends (OCL).

A shape of the lens 21 is not particularly limited. As the lens 21, a lens (so-called convex lens) formed in a convex shape having a curved surface convexly curved on the first surface side can be exemplified. Note that, in FIG. 2, a shape of the lens 21 is not particularly defined for convenience of description. The same applies to FIGS. 3, 5, and 7 to 17. Since the lens 21 is provided, it is easier to adjust light generated from the light emitting element 104 to be emitted from the display area 10A, and utilization efficiency of the light can be improved.

### (Filling Layer)

In the display area 10A, as illustrated in FIG. 2, the filling layer 28 is preferably provided so as to cover the first surface side of the lens 21. By providing the filling layer 28, the first surface side of the display area 10A can be smoothed, and the lens 21 and the light emitting element 104 can be protected from outside air and moisture. Similarly to the seal layer 29 described above, the filling layer 28 is preferably a layer having a function as a transparent adhesive layer. As a material of the filling layer 28, a resin material may be used similarly to the seal layer 29 described above.

Note that, in the example of FIG. 2, the filling layer 28 is distinguished from the seal layer 29 described above, but this is an example, and the present disclosure is not limited thereto. The filling layer 28 may be integrally formed with the seal layer 29. This can be specifically achieved, as illustrated in the example of FIG. 2, by forming the filling layer 28 on one surface so as to cover the entire first surface side of the second planarizing layer 25 including a portion displayed as the seal layer 29 illustrated in FIG. 2. In this case, the filling layer 28 also serves as the seal layer 29. Note that, in this case, the seal material 29A includes a material forming the filling layer 28, and the upper space 161 is also filled with the material forming the filling layer 28.

### (Sealing Substrate)

The sealing substrate 22 may be provided so as to cover the filling layer 28 (not illustrated). As the material of the sealing substrate 22, the material of the substrate 11 or the like can be used. For example, a glass substrate can be used as the sealing substrate 22. The material of the glass substrate is not limited to any particular material, as long as the glass substrate contains a material that transmits light emitted from the light emitting element 104. Examples of the material of the glass substrate include various glass substrates such as high strain point glass, soda glass, borosilicate glass, and lead glass, and quartz substrates.

### (Shape of End Portion of Sealing Substrate)

At the end portion 41 of the sealing substrate 22, the inclined portion 40 is preferably formed on the surface (second surface) side facing the light emitting element substrate 103. The inclined portion 40 forms, on the second surface of the sealing substrate 22, an inclined surface inclined downward from the position of the end surface 41A of the sealing substrate 22 toward the inside. The position of the proximal end 40A (inner end) of the inclined portion 40 is not particularly limited, but is preferably a position immediately above the bottom surface 128 of the groove 27A. In the example of FIG. 2, the inclined portion 40 forms a curved inclined surface, and the end surface 164 of the seal layer 29 is formed immediately below the proximal end 40A of the inclined portion 40. In this case, the position of the interface between the end surface coating portion 42 and the seal layer 29 to be described later can be located inside the bottom surface 128 of the groove 27A, and it becomes easy to form a state in which a part (portion 129A) of the in-groove space 129 is filled with the end surface coating portion 42 by substantially aligning the position of the end surface 164 of the seal layer 29 and the position of the outer end surface 162 of the first protective layer 16A with respect to the position in the inward and outward directions.

### (End Surface Coating Portion)

An end surface coating portion 42 is preferably provided in a portion between the light emitting element substrate 103 and the sealing substrate 22 so as to cover the outside of the seal layer 29. In the example of FIG. 2, the end surface coating portion 42 is in contact with the second wall portion 127B and a part of the bottom surface 128, fills the portion 129A of the in-groove space 129, and covers the end surface 164 of the seal layer 29 and the outer end surface 162 of the first protective layer 16A. The material of the end surface coating portion 42 is not particularly limited, but for example, the similar material as the coating layer, such as a resin material, can be exemplified. The end surface coating portion 42 covers the end surface and the like of the seal layer 29. Furthermore, the end surface coating portion 42 may cover not only the end surfaces of the seal layer 29 and the protective layer 16 but also the end surfaces of the inorganic insulating layer 12, the substrate 11, and the like depending on the layer structure.

### [1-2 Manufacturing Method]

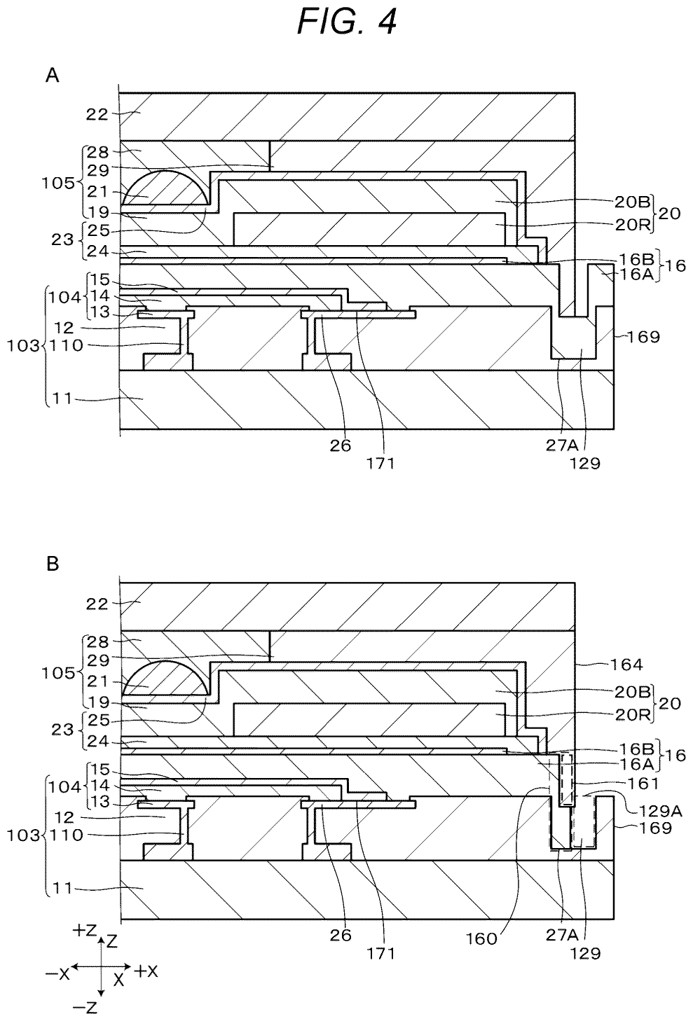

An example of the manufacturing method of the display device 10 will be continuously described. As illustrated in FIG. 3A, a circuit or the like is mounted on the substrate 11, the inorganic insulating layer 12 is formed, and the wiring 110, the auxiliary electrode 26, and the like are formed. In the inorganic insulating layer 12, a groove or a step (groove 27A in the example of FIG. 3A) is formed in the outer area 10B. As illustrated in FIG. 3B, the light emitting element substrate 103 is formed by further forming the light emitting element 104, and the protective layer 16 is formed on the first surface side of the light emitting element substrate 103. Moreover, as illustrated in FIG. 3C, the first planarizing layer 24, the color filter 18, the second planarizing layer 25, and the lens 21 are formed. At this time, the first color filter 19 and the second color filter 20 are formed as the color filter 18. The color filter 18 is an OCCF. Up to this point, a general manufacturing process of a display device may be performed. Next, the filling layer 28 is formed so as to cover the lens 21. Then, the periphery of the filling layer 28 is covered with the seal layer 29 (FIG. 3D). Moreover, as illustrated in FIG. 4A, the sealing substrate 22 is disposed. When the sealing substrate 22 is disposed, a force is applied from the sealing substrate 22 to the filling layer 28 and the seal layer 29, a gap between the filling layer 28 and the seal layer 29 is filled, and the end surface 164 of the seal layer 29 advances to the upper space 161 (FIG. 4B). The position of the end surface 164 of the seal layer 29 is substantially the position of the proximal end 40A of the inclined portion 40 in the sealing substrate 22 (in FIGS. 4A and 4B, description of the inclined portion 40 is omitted for convenience of description). Moreover, a portion of the protective layer 16 located outside the end surface 164 of the seal layer 29 is removed by etching processing (FIG. 4B). At this time, a part of the protective layer 16 formed inside the groove 27A is removed, and a part (portion 129A) of the in-groove space 129 is exposed. Then, the end surface coating portion 42 is formed so as to cover the outer end surface 162 of the first protective layer 16A and the end surface 164 of the seal layer 29. At this time, the portion 129A of the in-groove space 129 is filled with the end surface coating portion 42. Furthermore, an end surface 169 of the inorganic insulating layer 12 may also be covered with the end surface coating portion 42. Therefore, the display device 10 illustrated in FIG. 2 can be manufactured. The manufacturing method illustrated here is an example, and the manufacturing method of the display device 10 is not limited thereto.

### [1-3 Functions and Effects]

In the display device, when moisture enters from the outside and reaches the display area from the outer area, there is a possibility that a light emitting element or the like is damaged and a non-light emitting region is generated in the display area. Therefore, a display device is required to suppress moisture entry. As the entry path of moisture, a path along an interface of different layer structures and a path through the inside of a layer into which moisture is likely to enter are conceivable.

In the display device 10 according to the first embodiment, as illustrated in FIG. 2, the groove 27A is formed, and the covering portion 160 of the protective layer 16 is formed along the wall portion 127 and the bottom surface 128 so as to cover a part of the wall portion 127 and the bottom surface 128 of the groove 27A.

Therefore, the path length (the length of a moisture entry path N1) from the outer area to the display area through the interface between the inorganic insulating layer 12 and the protective layer 16 can be extended. Furthermore, even if moisture enters the protective layer 16, a stepped structure or a recessed structure is formed on the upper surface side of the covering portion 160 (the upper space 161 is formed), so that the length of the entry path (the length of a moisture entry path N2) through which moisture travels through the inside of the protective layer 16 and reaches the display area can be extended.

Furthermore, the upper space 161 is formed on the upper surface side (+Z direction side) of the forming portion of the covering portion 160 of the protective layer 16, and the seal layer 29 is embedded in the upper space 161. Even if a recessed structure or a stepped structure is formed on the first surface side of the covering portion 160 of the protective layer 16, it can be filled with the seal layer, and the smoothness (in FIG. 2, smoothness of the first surface side of the seal layer 29) of the first surface side in the display device 10 can be maintained.

### [1-4 Modifications]

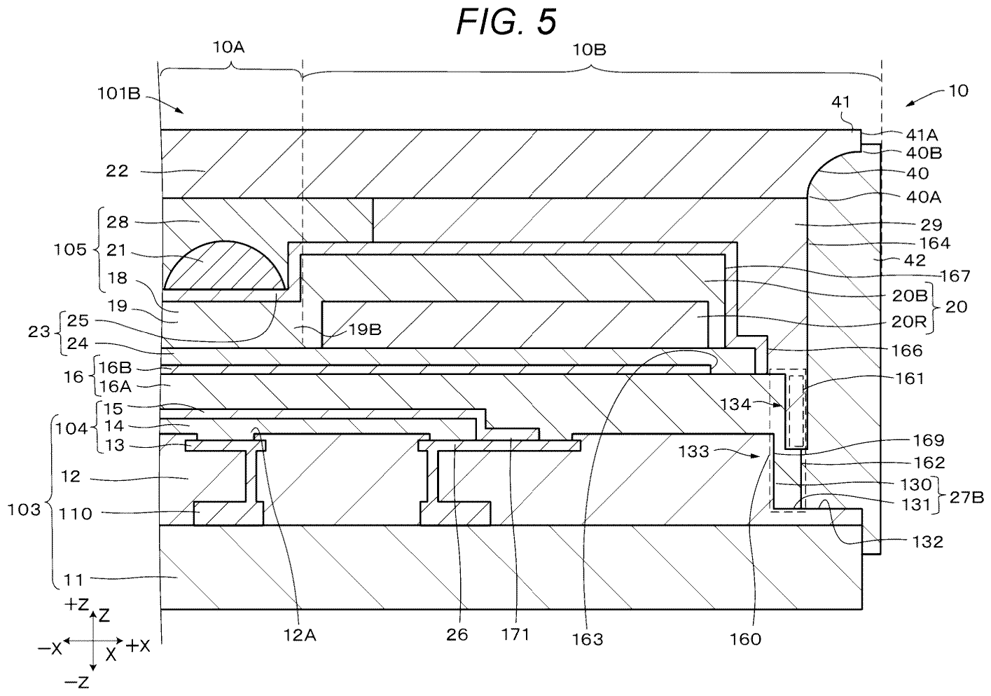

In the display device 10 of the first embodiment, the inorganic insulating layer 12 has the groove 27A in the example of FIG. 2, but the present invention is not limited thereto. In the inorganic insulating layer 12, for example, a step 27B as illustrated in FIG. 5 may be formed instead of the groove 27A. Such a mode is referred to as a modification of the first embodiment. FIG. 5 is a cross-sectional view illustrating an example of the display device 10 according to the modification of the first embodiment. The display device is similar to the display device 10 of the first embodiment illustrated in FIG. 2 described above and the like except for the step 27B and the structure covering the step 27B.

### (Step)

The step 27B is formed near the outer end portion of the outer area 10B. In the example of FIG. 5, the step 27B forms a step structure (a step structure that becomes the first height difference portion 133 due to the step 27B) on the end surface 169 of the outer end of the inorganic insulating layer 12. The step structure is a structural part that forms a difference (height difference) in position (position in the Z-axis direction) in the height direction with respect to the first surface of the inorganic insulating layer 12. Note that, in a case where the Z-axis direction is a line-of-sight direction, a wall portion 130 of the step 27B is preferably formed at a position closer to the display area 10A than the proximal end 40A of the inclined portion 40 (a position on the −X direction side in FIG. 5).

### (Covering Portion)

In the example of FIG. 5, the covering portion 160 of the protective layer 16 includes the first protective layer 16A. The covering portion 160 is formed so as to be in contact with at least a part of a bottom surface 131 connected to the wall portion 130 forming the step 27B at the lower end of the wall portion 130 of the step 27B and to cover the wall portion 130 and a part of the bottom surface 131. The covering portion 160 forms the second height difference portion 134, the upper space 161 is formed above the covering portion 160, and the seal layer 29 fills the upper space 161.

### (End Surface Coating Portion)

The end surface coating portion 42 is formed so as to be in contact with the end surface of the protective layer 16 (the outer end surface 162 of the first protective layer 16A in the example of FIG. 5) and the end surface 164 of the seal layer 29 and to cover the outer end surface 162 and the end surface 164.

Furthermore, the end surface coating portion 42 covers a part of the end surface 169 of the surface of the inorganic insulating layer 12 and a part (portion 132) of the bottom surface exposed to the outside from the covering portion 160.

Also, in the display device 10 according to a first modification of the first embodiment, it is possible to obtain the similar effects to those shown in [1-3 Functions and Effects] described above.

### 2 Second Embodiment

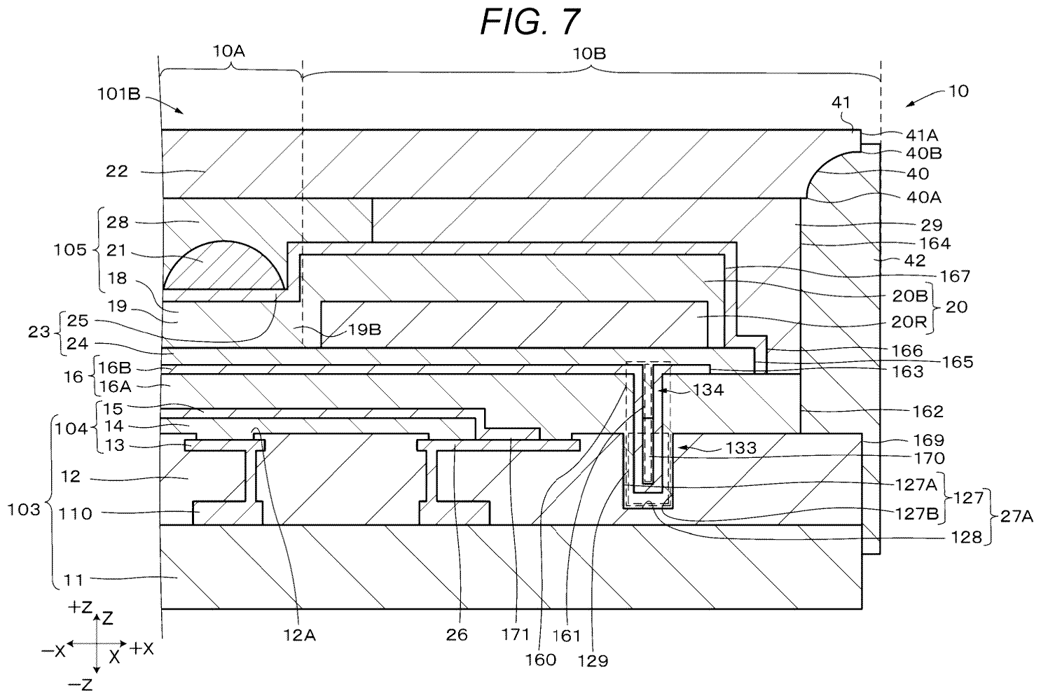

As illustrated in FIG. 7, a display device 10 according to the second embodiment forms a groove or a step at a lower position of the color filter 18. The display device 10 according to the second embodiment is similar to that of the first embodiment except for a position where a groove or a step is formed.

Hereinafter, a description of the configuration similar to that of the first embodiment are redundant and thus will be omitted. The same similarly applies to each embodiment described below in a third embodiment. FIG. 7 is a cross-sectional view schematically illustrating an example of the display device according to the second embodiment.

### (Groove or Step)

In the display device 10 according to the second embodiment, a groove or a step is formed in the inorganic insulating layer 12. In the example of FIG. 7, a groove 27A is formed in the inorganic insulating layer 12. In a case where the thickness direction (Z-axis direction) of the light emitting element substrate 103 is a line-of-sight direction, the groove 27A is formed at a lower position (position immediately below) of the second color filter 20. The groove 27A may be formed in an annular shape similarly to the first embodiment.

### (Protective Layer)

In the example of FIG. 7, the protective layer 16 has a multilayer structure of the first protective layer 16A and the second protective layer 16B similarly to the first embodiment. In this example, the covering portion 160 of the protective layer 16 also has a multilayer structure of the first protective layer 16A and the second protective layer 16B. Furthermore, the covering portion 160 is in contact with the wall portion 127 (the first wall portion 127A and the second wall portion 127B) of the groove 27A and the bottom surface 128, and fills at least a part of the in-groove space 129. The covering portion 160 forms a recessed structure to be the second height difference portion 134 on the upper surface side (first surface side), and forms the upper space 161 inside the recessed structure.

### (Planarizing Layer)

As the planarizing layer 23, a first planarizing layer 24 covering at least a part of the protective layer 16 and a second planarizing layer 25 covering the color filter 18 are formed. The second planarizing layer 25 is formed in the similar manner similarly to the first embodiment. The first planarizing layer 24 is formed in a region that covers the groove 27A in plan view of the light emitting element substrate 103. The first planarizing layer 24 covers the upper side of the second height difference portion 134 of the protective layer 16, that is, covers the upper space 161 formed at the position of the covering portion 160. The first planarizing layer 24 is preferably formed so as to fill the upper space 161 (formed so as to avoid formation of a cavity 170), but is not limited thereto. In the example of FIG. 7, the cavity 170 is formed so as to close the upper opening of the upper space 161 and is surrounded by the covering portion 160 and the first planarizing layer 24. The first planarizing layer 24 preferably contains a material having excellent hygroscopicity. Furthermore, the first planarizing layer 24 is preferably a layer having a hygroscopic member. Since the first planarizing layer 24 has the hygroscopic member and closes the upper opening of the upper space 161 formed on the upper side of the groove 27A, moisture is easily removed from the outside by the hygroscopic member of the first planarizing layer 24. Therefore, moisture is less likely to enters the display area 10A through the inside of the first planarizing layer 24, and moisture is less likely to enter along the interface between the first planarizing layer 24 and the second protective layer 16B.

### (Color Filter)

As the color filter 18, a first color filter 19 and a second color filter 20 are formed similarly to the first embodiment. In the display device 10 according to the second embodiment, in a case where the thickness direction of the light emitting element substrate 103 is a line-of-sight direction, the groove 27A is formed on the lower side of the formation region of the second color filter 20.

According to the display device 10 according to the second embodiment, similar effects to those of the first embodiment can be obtained.

In the display device 10 according to the second embodiment, since the upper space 161 formed on the upper surface of the covering portion 160 formed on the groove 27A is covered with the first planarizing layer 24, the flatness on the first surface side can be improved. Therefore, the second color filter 20 can be closely formed as the functional layer 105 on the first planarizing layer 24 (the upper side of the upper space 161).

### 3 Third Embodiment

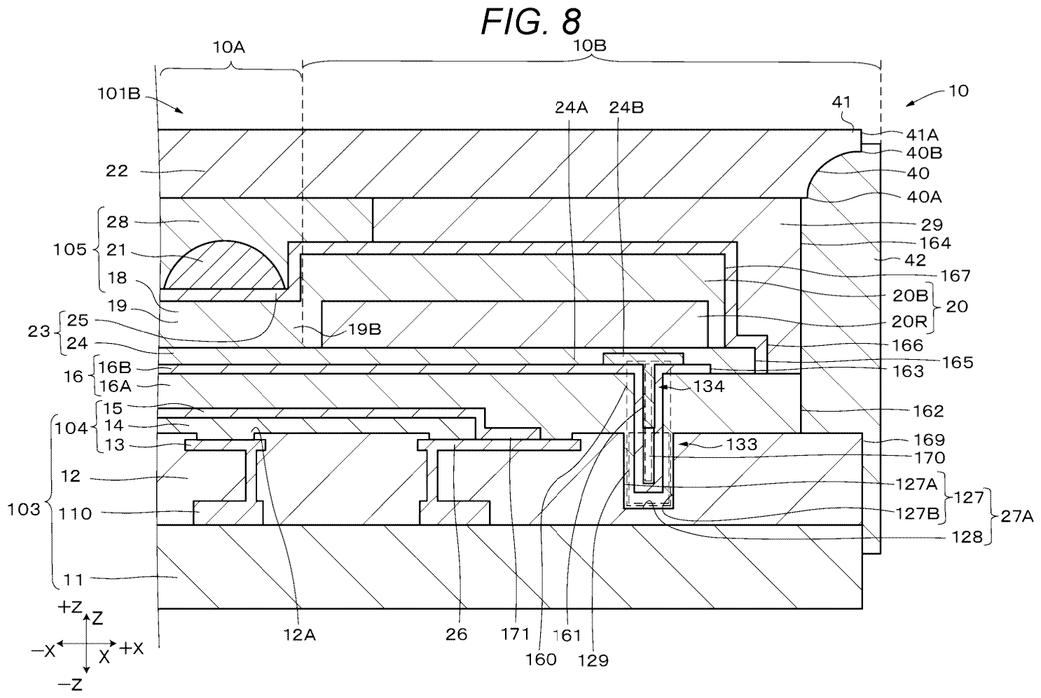

In a display device 10 according to the third embodiment, as illustrated in FIG. 8, the first planarizing layer 24 has a structure in which an upper planarizing layer 24A and a lower planarizing layer 24B are laminated. The display device 10 according to the third embodiment is similar to the display device according to the second embodiment except for the structure of the first planarizing layer 24.

Hereinafter, a description of the configuration similar to that of the first and second embodiments are redundant and thus will be omitted. FIG. 8 is a cross-sectional view schematically illustrating an example of the display device 10 according to the third embodiment.

### (Groove or Step)

In the display device 10 according to the third embodiment, a groove or a step is formed in the inorganic insulating layer 12. In the example of FIG. 8, a groove 27A is formed in the inorganic insulating layer 12. In a case where the thickness direction (Z-axis direction) of the light emitting element substrate 103 is a line-of-sight direction, the groove 27A is formed at a lower position (position immediately below) of the second color filter 20 and is formed on the lower side of the lower planarizing layer 24B. The groove 27A may be formed in an annular shape similarly to the first embodiment.

### (Planarizing Layer)

As the planarizing layer 23, a first planarizing layer 24 covering at least a part of the protective layer 16 and a second planarizing layer 25 covering the color filter 18 are formed. The second planarizing layer 25 is formed in the similar manner similarly to the first embodiment. As described above, the first planarizing layer 24 has a structure in which the upper planarizing layer 24A and the lower planarizing layer 24B are laminated. The upper planarizing layer 24A is formed in the display area 10A and the outer area 10B with the thickness direction of the light emitting element substrate 103 as the line-of-sight direction. The lower planarizing layer 24B is formed in the outer area 10B with the thickness direction of the light emitting element substrate 103 as the line-of-sight direction, and is formed in a region that covers the groove 27A with the covering portion 160 interposed therebetween. The lower planarizing layer 24B covers the upper space 161 formed on the upper surface side of the covering portion 160 of the protective layer 16. The lower planarizing layer 24B is preferably formed so as to fill the upper space 161, but is not limited thereto. In the example of FIG. 8, the lower planarizing layer 24B is formed so as to close the upper opening of the upper space 161, and a cavity 170 surrounded by the covering portion 160 and the lower planarizing layer 24B is formed. The lower planarizing layer 24B preferably contains a material having excellent hygroscopicity. Furthermore, the lower planarizing layer 24B is preferably a layer having a hygroscopic member. In the first planarizing layer 24, a hygroscopic member may be blended only in the lower planarizing layer 24B of the upper planarizing layer 24A and the lower planarizing layer 24B. In this case, since the first planarizing layer 24 provided in the display area 10A is the upper planarizing layer 24A, blending of the hygroscopic member is avoided in the portion of the first planarizing layer 24 on the display area 10A. Therefore, it is possible to eliminate the need to consider the possibility that the traveling of light generated from the light emitting element 104 is affected by the hygroscopic member when passing through the first planarizing layer 24. Furthermore, since the lower planarizing layer 24B has the hygroscopic member and closes the upper space 161 formed on the upper side of the groove 27A, in a case where moisture enters along the interface between the first planarizing layer 24 and the second protective layer 16B, the boundary between the lower planarizing layer 24B and the second protective layer 16B exists in a part of the moisture entry path, and when moisture entered from the outside reaches the boundary between the lower planarizing layer 24B and the second protective layer 16B, the moisture can be easily removed by the hygroscopic member of the lower planarizing layer 24B.

According to the display device 10 according to the third embodiment, similar effects to those of the first embodiment can be obtained.

### 4 Fourth Embodiment

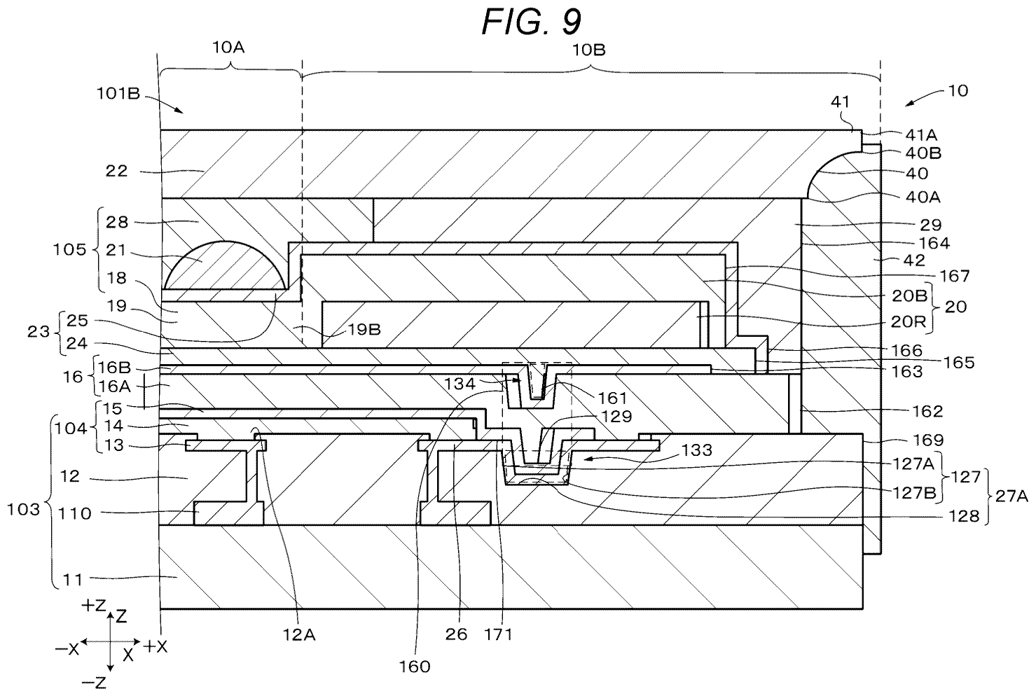

In a display device 10 according to the fourth embodiment, as illustrated in FIG. 9, a groove or a step is formed in a formation region of the auxiliary electrode 26. The display device 10 according to the fourth embodiment is similar to that of the first embodiment except for a position where a groove or a step is formed. Hereinafter, a description of the configuration similar to that of the first embodiment are redundant and thus will be omitted. FIG. 9 is a cross-sectional view schematically illustrating an example of the display device 10 according to the fourth embodiment.

### (Groove or Step)

In the display device 10 according to the fourth embodiment, a groove or a step is formed in the inorganic insulating layer 12. In the example of FIG. 9, a groove 27A is formed in the inorganic insulating layer 12. The groove 27A is formed below the auxiliary electrode 26 in a case where the thickness direction of the light emitting element substrate 103 is a line-of-sight direction. In particular, as illustrated in the example of FIG. 9, the groove 27A is preferably formed immediately below a connecting part 171 between the auxiliary electrode 26 and the second electrode 15. The auxiliary electrode 26 is usually formed in an annular shape in the outer area 10B, and the groove 27A may be formed in an annular shape similarly to the auxiliary electrode 26.

### (Auxiliary Electrode)

In the example of FIG. 9, the auxiliary electrode 26 is formed so as to be in contact with the wall portion 127 (the first wall portion 127A and the second wall portion 127B) and the bottom surface 128 of the groove 27A and to cover the wall portion 127 and the bottom surface 128. The auxiliary electrode 26 is electrically connected to the second electrode 15 in a predetermined region on the first surface side.

### (Connecting Part Between Auxiliary Electrode and Second Electrode)

The second electrode 15 constituting the light emitting element 104 is connected to the auxiliary electrode 26. The connecting part 171, which is a portion where the second electrode 15 and the auxiliary electrode 26 are connected to each other, is preferably formed in a region covering a portion including at least a part of a portion corresponding to the groove 27A. Since the connecting part 171 is present in the region covering at least a part of the portion corresponding to the groove 27A, the connection area between the second electrode 15 and the auxiliary electrode 26 can be increased, and the contact resistance between the second electrode 15 and the auxiliary electrode 26 can be reduced.

### (Protective Layer)

In the example of FIG. 9, the protective layer 16 has a multilayer structure of the first protective layer 16A and the second protective layer 16B similarly to the first embodiment. The covering portion 160 of the protective layer 16 also has a multilayer structure of the first protective layer 16A and the second protective layer 16B. Furthermore, the covering portion 160 covers the groove 27A with the connecting part 171 interposed therebetween. In the example of FIG. 9, the covering portion 160 forms a recessed structure on the upper side (first surface side) of the groove 27A, and forms the upper space 161 inside the recessed structure.

### (First Planarizing Layer)

The first planarizing layer 24 is formed so as to cover the protective layer 16 and fills the upper space 161. The first planarizing layer 24 is preferably excellent in hygroscopicity. The first planarizing layer 24 may be a layer containing a hygroscopic member.

According to the display device 10 according to the fourth embodiment, similar effects to those of the first embodiment can be obtained.

### 5 Fifth Embodiment

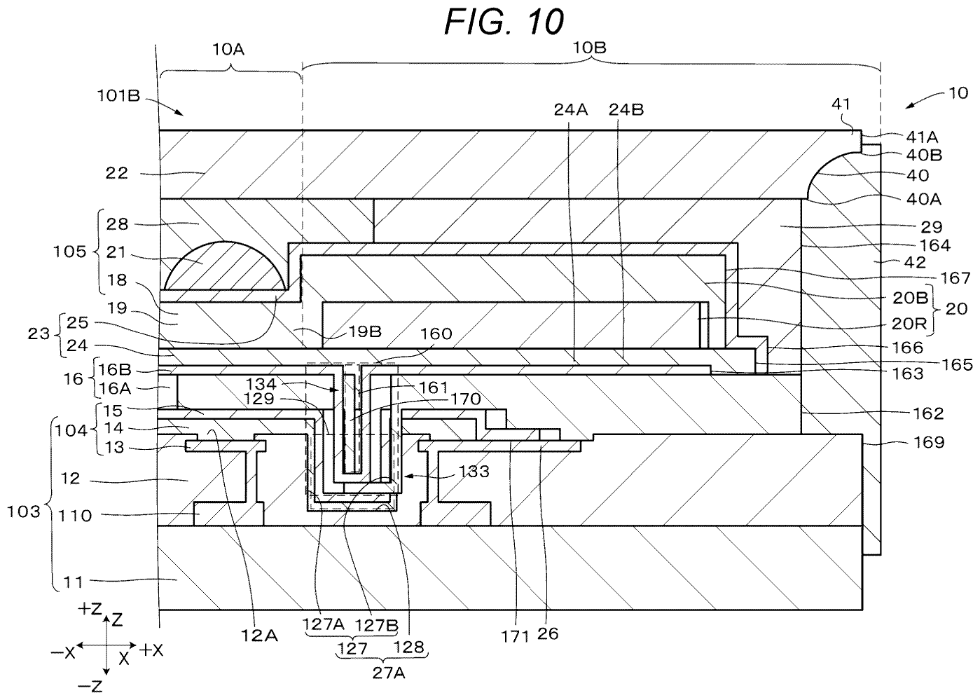

In a display device 10 according to the fifth embodiment, as illustrated in FIG. 10, a groove or a step is provided at a position closer to the display area 10A side (a position on the −X direction side in FIG. 10) than the formation region of the auxiliary electrode 26. However, the groove or the step is provided outside the display area 10A (outer area 10B (+X direction side in FIG. 10)). The display device 10 according to the fifth embodiment is similar to that of the first embodiment except for a position where a groove or a step is formed. Hereinafter, a description of the configuration similar to that of the first embodiment are redundant and thus will be omitted. FIG. 10 is a cross-sectional view schematically illustrating an example of the display device 10 according to the fifth embodiment.

### (Groove or Step)

In the display device 10 according to the fifth embodiment, a groove or a step is formed in the inorganic insulating layer 12. In the example of FIG. 10, a groove 27A is formed in the inorganic insulating layer 12. In a case where the thickness direction of the light emitting element substrate 103 is a line-of-sight direction, the groove 27A is formed at a position closer to the display area 10A side than the formation region of the auxiliary electrode 26 and at a position outside the display area 10A (position of the outer area 10B). More specifically, the groove 27A is formed between the first electrode 13 and the auxiliary electrode 26 which are located outermost among the first electrodes 13 forming the light emitting element 104. The groove 27A may be formed in an annular shape in the outer area 10B.

### (Organic Layer and Second Electrode)

In the example of FIG. 10, the organic layer 14 and the second electrode 15 constituting the light emitting element 104 are formed in the display area 10A, and are continuously formed from the display area 10A to a predetermined region of the outer area 10B. The organic layer 14 and the second electrode 15 are connected to the auxiliary electrode 26. The organic layer 14 is preferably formed so as to cover a portion including at least a part of the groove 27A in a case where the thickness direction of the light emitting element substrate 103 is a line-of-sight direction. The second electrode 15 is preferably formed so as to cover a portion including at least a part of the groove 27A with the organic layer 14 interposed therebetween. In the example of FIG. 10, the organic layer 14 covers the wall portion 127 and the bottom surface 128 of the groove 27A. The second electrode 15 covers the wall portion 127 and the bottom surface 128 of the groove 27A with the organic layer 14 interposed therebetween.

### (Protective Layer)

In the example of FIG. 10, the protective layer 16 has a multilayer structure of a first protective layer 16A and a second protective layer 16B similarly to the first embodiment. The covering portion 160 of the protective layer 16 also has a multilayer structure of the first protective layer 16A and the second protective layer 16B. The covering portion 160 covers the groove 27A with the organic layer 14 and the second electrode 15 interposed therebetween. In the example of FIG. 10, the covering portion 160 is in contact with the first surface of the second electrode 15 on the second surface side, forms a recessed structure on the upper surface side (first surface side) of the groove 27A, and forms the upper space 161 inside the recessed structure.

### (First Planarizing Layer)

The first planarizing layer 24 is formed so as to cover the protective layer 16 and covers the upper space 161. In the example of FIG. 10, a cavity 170 is formed between the first planarizing layer 24 and the covering portion 160. However, this does not prohibit the first planarizing layer 24 from being formed so as to fill the upper space 161. The first planarizing layer 24 is preferably excellent in hygroscopicity. The first planarizing layer 24 may be a layer containing a hygroscopic member.

According to the display device 10 according to the fifth embodiment, similar effects to those of the first embodiment can be obtained. Furthermore, in the display device 10 according to the fifth embodiment, since the organic layer 14 is formed so as to cover the wall portion 127 and the bottom surface 128 of the groove 27A, the moisture transmission path can be extended even in a case where moisture enters along the interface between the organic layer 14 and the layer in contact with the organic layer 14, or in a case where moisture enters through the inside of the organic layer 14.

### 6 Sixth Embodiment

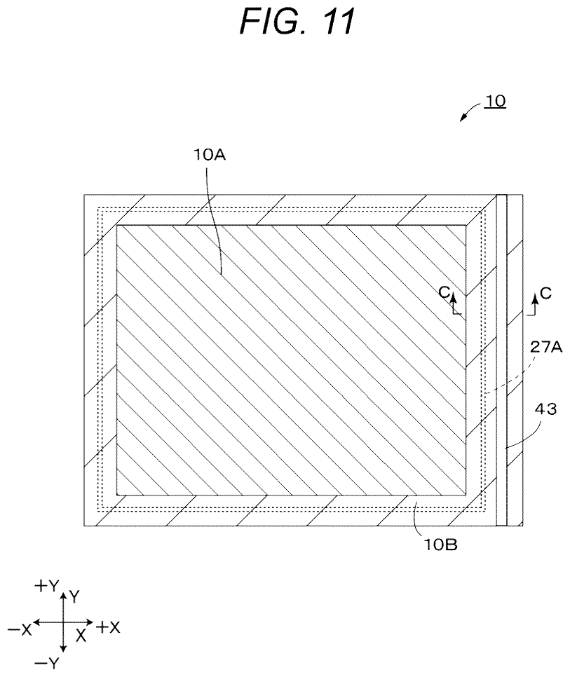

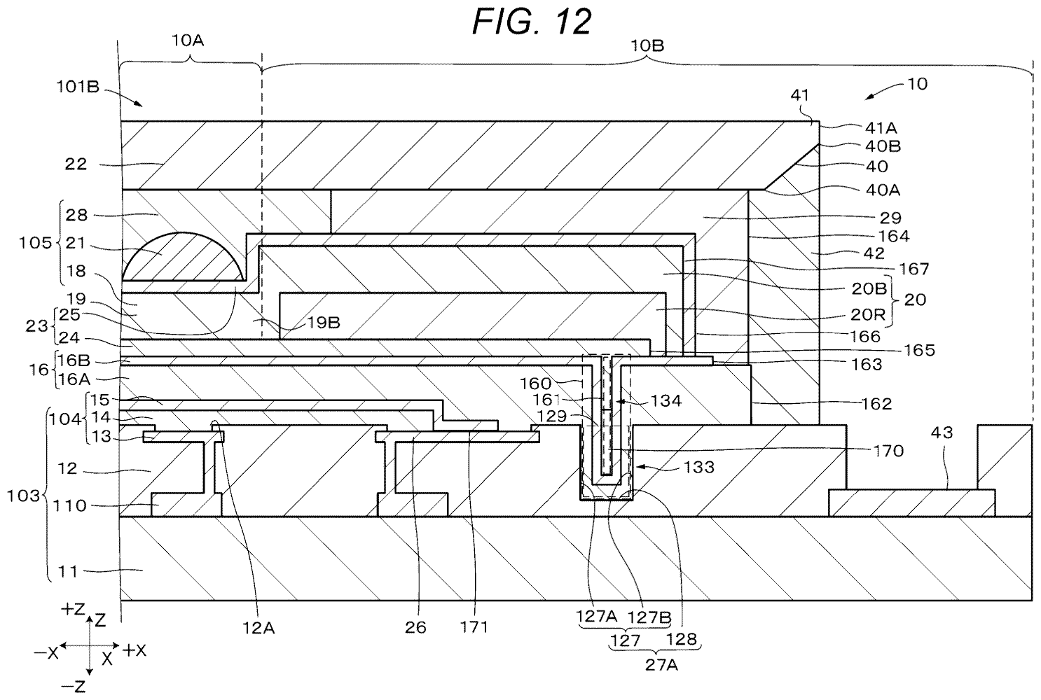

As illustrated in FIGS. 11 and 12, a display device 10 according to the sixth embodiment is provided with a connection terminal 43. However, the connection terminal 43 is provided outside a groove or a step. FIGS. 11 and 12 are a plan view and a cross-sectional view schematically illustrating an example of the display device 10 according to the sixth embodiment. In one example of the display device 10 according to the sixth embodiment illustrated in FIGS. 11 and 12, the position of the end surface 165 of the first planarizing layer 24 is formed at a position closer to the display area 10A than the end surface 167 of the second color filter 20, and the second color filter 20 is covered with the second planarizing layer 25. An example of the display device 10 according to the sixth embodiment is similar to the second embodiment except for the configurations of the first planarizing layer 24, the second planarizing layer 25, and the connection terminal 43. Hereinafter, a description of the configuration similar to that of the second embodiment are redundant and thus will be omitted. Note that, hereinafter, the description of the seventh embodiment to the eleventh embodiment will be continued while taking, as an example, a case where a new configuration is provided with respect to the configuration of the sixth embodiment.

### (Connection Terminal)

In the display device 10, the connection terminal 43 is formed in the outer area 10B and outside (+X direction side in FIGS. 11 and 12) the groove or the step. The connection terminal 43 is formed outside the end surface coating portion 42. The connection terminal 43 functions as a terminal for electrically connecting various circuits provided on the substrate 11 to external devices such as another control circuit substrate. The connection terminal 43 is formed on the substrate 11. The connection terminal 43 is preferably a pad formed by a conductive member such as metal. An inorganic insulating layer 12 is formed around the connection terminal 43. The end surface of the connection terminal 43 may be covered with the inorganic insulating layer 12. The layout of the connection terminal 43 is not particularly limited, but extends in one direction (Y-axis direction in FIG. 11) in the example of FIG. 11.

### (First Planarizing Layer and Second Planarizing Layer)

The first planarizing layer 24 is formed so as to cover the upper space 161 similarly to the second embodiment. The end surface 165 of the first planarizing layer 24 is located closer to the outer area 10B (in FIG. 12, a −X direction side) than the outer end surface 163 of the second protective layer 16B and the end surface 167 of the second color filter. The end surface 165 of the first planarizing layer 24 is covered with the second color filter 20. Note that the second planarizing layer 25 covers the end surface 167 at the outer end of the second color filter 20.

### (Sealing Substrate)

In the display device 10 according to the sixth embodiment, the sealing substrate 22 is provided so as to cover the filling layer 28 and the seal layer 29. In a case where the Z-axis direction is a line-of-sight direction, the position of the end surface 41A of the sealing substrate 22 is a position closer to the display area 10A than the connection terminal 43. An inclined portion 40 is formed in a predetermined portion inward from the position of the end surface 41A of the sealing substrate 22. In the example of FIG. 12, the inclined portion 40 forms an inclined plane.

Note that, in the display device 10 according to the sixth embodiment, the position of the outer end surface (in the example of FIG. 12, the outer end surface 162 of the first protective layer 16A) of the protective layer 16 and the position of the end surface 164 of the seal layer 29 are preferably located closer to the display area 10A than the position of the proximal end 40A of the inclined portion 40. In this case, the end surface coating portion 42 is formed immediately below the proximal end 40A of the inclined portion 40, and the end surface coating portion 42 covers the outer end surface 162 of the first protective layer 16A and the end surface 164 of the seal layer 29. Then, in the example of FIG. 12, the lower end (end on the second surface side) of the end surface coating portion 42 is in contact with the inorganic insulating layer 12. Since the end surface coating portion 42 is formed in this manner, it is easy to more effectively block moisture from entering into the protective layer 16, the color filter 18, and the like from the outside.

In the display device 10 according to the sixth embodiment, the position of the outer end surface 162 of the first protective layer 16A exists outside the groove 27A (in FIG. 12, +X direction side), and the first protective layer 16A is formed so as to be in contact with the wall portion 127 and the bottom surface 128 of the groove 27A and cover the wall portion 127 and the bottom surface 128, so that it is possible to extend the moisture entry path along the interface between the first protective layer 16A and the layer in contact with the first protective layer 16A. According to the display device 10 of the sixth embodiment, when the outer end of the first protective layer 16A is removed before the end surface coating portion 42 is provided at the time of manufacturing the display device 10, even if moisture enters from the first protective layer 16A, the moisture hardly reaches the display area along the interface between the first protective layer 16A and the layer in contact with the first protective layer 16A.

Furthermore, according to the display device 10 according to the sixth embodiment, moisture hardly reaches the display area 10A along the inside of the first protective layer 16A.

In the display device 10 according to the sixth embodiment, similarly to the second embodiment, since the upper space 161 formed on the upper surface of the covering portion 160 formed on the groove 27A is covered with the first planarizing layer 24, the flatness on the first surface side can be improved even if the recessed structure by the upper space 161 is formed on the first surface side. Therefore, the second color filter 20 can be closely formed as the functional layer 105 on the first planarizing layer 24 (the upper side of the upper space 161).

### 7. Seventh Embodiment

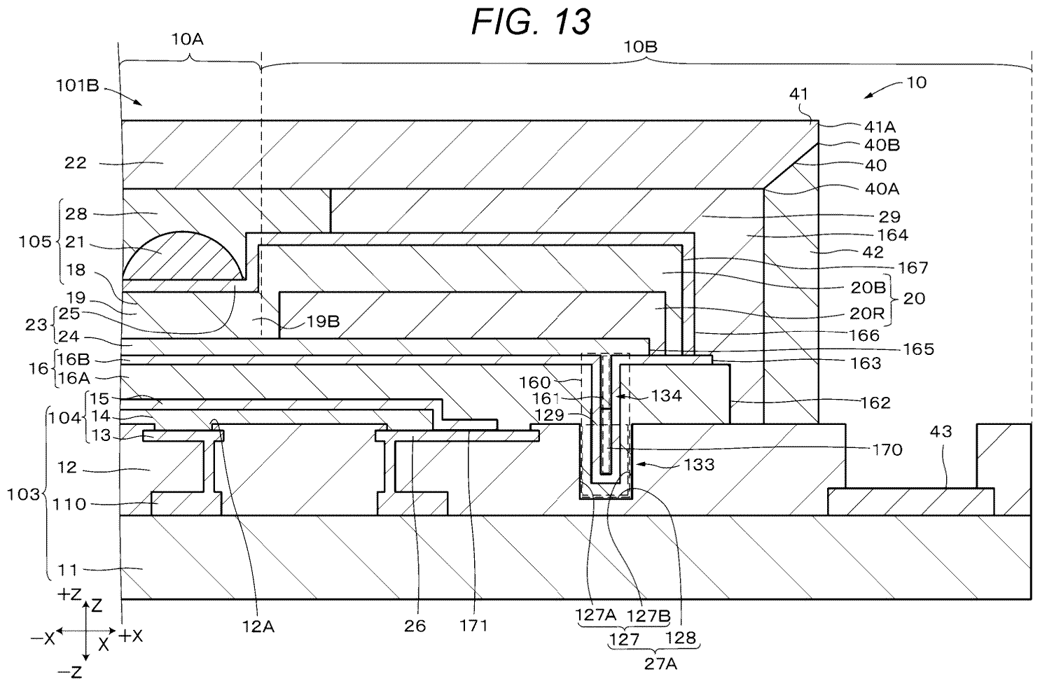

In a display device 10 according to the seventh embodiment, as illustrated in FIG. 13, the outer end surface 162 of the first protective layer 16A is covered with a seal layer 29. FIG. 13 is a cross-sectional view schematically illustrating an example of the display device 10 according to the seventh embodiment. An example of the display device 10 according to the seventh embodiment illustrated in FIG. 13 is similar to the display device according to the sixth embodiment except for a configuration in which the outer end surface 162 of the first protective layer 16A is covered with the seal layer 29. Hereinafter, a description of the configuration similar to that of the sixth embodiment are redundant in the description of the seventh embodiment, and thus will be omitted.

### (First Protective Layer)

The first protective layer 16A is formed so as to cover the groove 27A similarly to the sixth embodiment. In a case where the Z-axis direction is a line-of-sight direction, the outer end surface 162 of the first protective layer 16A is located outside the outer end surface 163 of the second protective layer. The outer end surface 162 of the first protective layer 16A is located inside (−X direction side) the position of the end surface 164 of the seal layer 29. Note that the end surface 164 is covered with the seal layer 29.

### (Covering Portion)

Note that, similarly to the sixth embodiment, the covering portion 160 of the protective layer 16 has a multilayer structure of the first protective layer 16A and the second protective layer 16B, and is in contact with the wall portion 127 and the bottom surface 128 of the groove 27A and covers the wall portion 127 and the bottom surface 128.

According to the display device according to the seventh embodiment, similar effects to those of the sixth embodiment can be obtained.

### 8. Eighth Embodiment

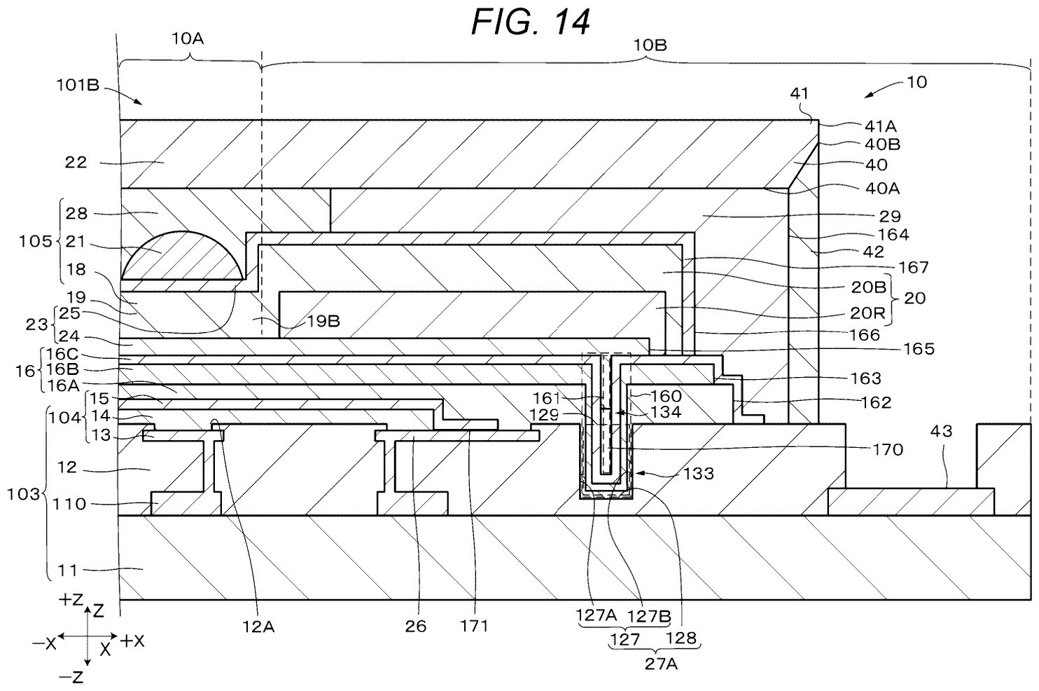

In a display device according to the eighth embodiment, as illustrated in FIG. 14, the protective layer 16 has a multilayer structure of three layers, and the outermost end surface of the protective layer 16 is covered with the seal layer 29. FIG. 14 is a cross-sectional view schematically illustrating an example of the display device 10 according to the eighth embodiment. An example of the display device 10 according to the eighth embodiment illustrated in FIG. 14 is similar to the display device 10 according to the sixth embodiment except for a configuration in which the protective layer 16 has a multilayer structure of three layers and the outer end surface of the protective layer 16 is covered with the seal layer 29. Hereinafter, a description of the configuration similar to that of the sixth embodiment are redundant and thus will be omitted.

### (Protective Layer)

In the example of FIG. 14, the protective layer 16 has a multilayer structure in which a first protective layer 16A, a second protective layer 16B, and a third protective layer 16C are laminated in this order from the side closer to the light emitting element substrate 103. Each of the first protective layer 16A, the second protective layer 16B, and the third protective layer 16C may be either an inorganic layer or an organic layer. For example, the first protective layer 16A and the third protective layer 16C may be inorganic layers, and the second protective layer 16B may be organic layers. As described above, the protective layer 16 may have a structure in which an inorganic layer and an organic layer are laminated.

### (Covering Portion)

In the example of FIG. 14, the covering portion 160 of the protective layer 16 has a multilayer structure of a first protective layer 16A, a second protective layer 16B, and a third protective layer 16C. Furthermore, the covering portion 160 is in contact with the wall portion 127 (the first wall portion 127A and the second wall portion 127B) and the bottom surface 128 of the groove 27A and covers the wall portion 127 and the bottom surface 128. The covering portion 160 forms a recessed structure on the upper surface side (first surface side), and forms the upper space 161 inside the recessed structure.

The third protective layer 16C is formed so as to cover the outer end surface 162 of the first protective layer 16A and the outer end surface 163 of the second protective layer 16B, and the outer end surface of the protective layer 16 includes the third protective layer 16C. The outer end of the third protective layer 16C extends in the outer direction (+X direction in FIG. 14) so as to be in contact with the inorganic insulating layer 12.

### (Seal Layer)

The seal layer 29 covers the third protective layer 16C, and covers the outer end surface 162 of the first protective layer 16A and the outer end surface 163 of the second protective layer 16B with the third protective layer 16C interposed therebetween.

In the display device 10 according to the eighth embodiment, the protective layer 16 has a multilayer structure of three layers, the outer end surface 162 of the first protective layer 16A is covered with the third protective layer 16C, and the outer side of the third protective layer 16C is covered with the seal layer 29. Therefore, it is possible to suppress the possibility that moisture enters from the outside to the first protective layer 16A.

### 9. Ninth Embodiment

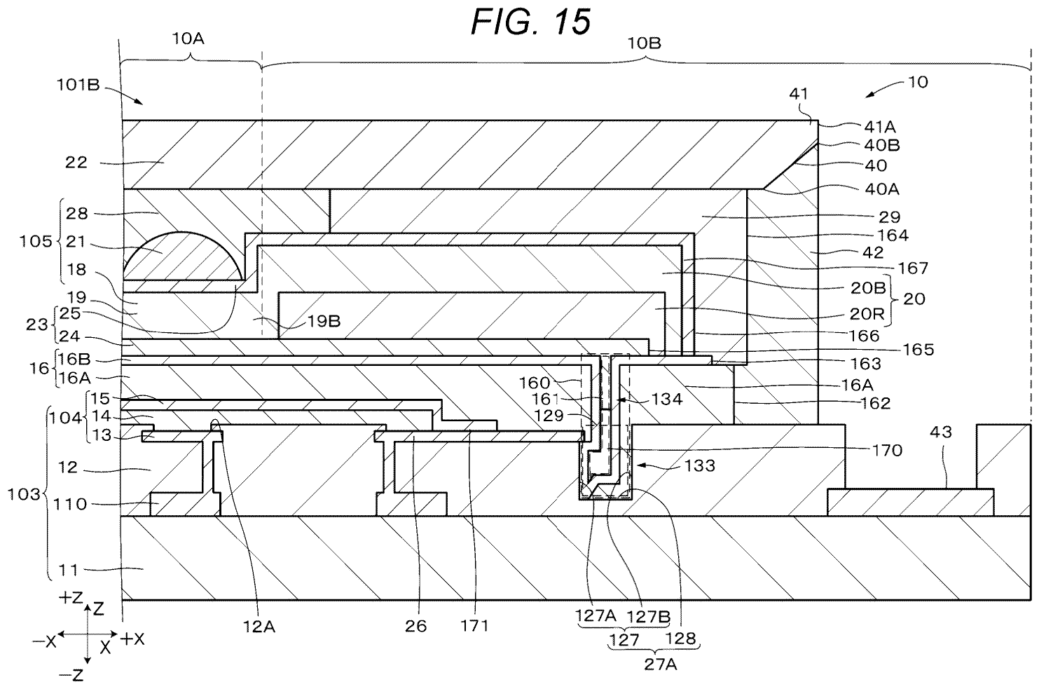

In a display device 10 according to the ninth embodiment, as illustrated in FIG. 15, the covering portion 160 of the protective layer 16 partially includes the second protective layer 16B. FIG. 15 is a cross-sectional view schematically illustrating an example of the display device according to the ninth embodiment. An example of the display device according to the ninth embodiment illustrated in FIG. 15 may be similar to the display device according to the sixth embodiment except for the configuration of the covering portion 160. Hereinafter, a description of the configuration similar to that of the sixth embodiment are redundant and thus will be omitted.

### (Groove or Step)

In the display device 10 according to the ninth embodiment, a groove or a step is formed in the inorganic insulating layer 12. In the example of FIG. 15, a groove 27A is formed in the inorganic insulating layer 12. The groove 27A is formed below the second color filter 20 in a case where the thickness direction of the light emitting element substrate 103 is a line-of-sight direction. The groove 27A may be formed in an annular shape similarly to the first embodiment or the like.

### (Protective Layer and Covering Portion)

In the example of FIG. 15, the protective layer 16 has a multilayer structure in which a first protective layer 16A and a second protective layer 16B are laminated. The covering portion 160 of the protective layer 16 has a portion having a multilayer structure of the first protective layer 16A and the second protective layer 16B and a portion including the second protective layer 16B (a portion indicated by reference numeral 132 in FIG. 15). The covering portion 160 covers the wall portion 127 (the first wall portion 127A and the second wall portion 127B) and the bottom surface 128 of the groove 27A. In the example of FIG. 15, the portion 132 of the covering portion 160 including the second protective layer 16B is formed so as to be in contact with the first wall portion 127A along the first wall portion 127A of the groove 27A. However, this is an example, and the portion 132 may be formed in a portion of the covering portion 160 covering the second wall portion 127B and the bottom surface 128. In the display device 10, a recessed structure is formed on an upper surface side (first surface side) of the covering portion 160, and the upper space 161 is formed inside the recessed structure. Note that the opening of the upper space 161 is covered with the first planarizing layer 24.

### (Auxiliary Electrode)

In the display device 10 according to the ninth embodiment, the auxiliary electrode 26 is formed in a region (region on the −X direction side) closer to the display area 10A than the groove 27A. As illustrated in FIG. 15, the auxiliary electrode 26 may extend to the upper end edge of the groove 27A. This is not limited to the ninth embodiment, and is similarly applied to other embodiments. In this case, the auxiliary electrode 26 preferably has a light shielding property. Since the auxiliary electrode 26 has a light shielding property and extends to the groove 27A, the auxiliary electrode 26 can function as an eaves portion that suppresses entry of light into the inorganic insulating layer 12.

### 10. Tenth Embodiment

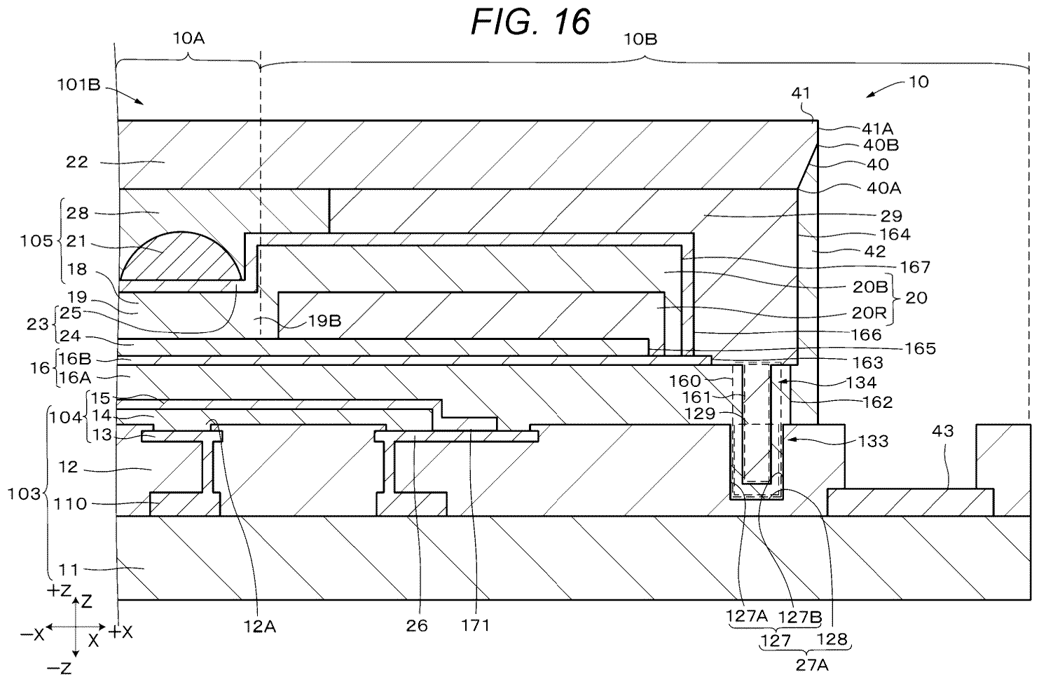

As illustrated in FIG. 16, in a display device 10 according to the tenth embodiment, a groove 27A is formed outside the second color filter 20. FIG. 16 is a cross-sectional view schematically illustrating an example of the display device 10 according to the tenth embodiment. An example of the display device 10 according to the tenth embodiment illustrated in FIG. 16 is similar to the sixth embodiment except that the position of the groove 27A is a predetermined position outside the second color filter 20. Hereinafter, a description of the configuration similar to that of the sixth embodiment are redundant and thus will be omitted.

### (Groove or Step)

In the display device 10 according to the tenth embodiment, a groove or a step is formed in the inorganic insulating layer 12. In the example of FIG. 16, a groove 27A is formed in the inorganic insulating layer 12. In a case where the thickness direction of the light emitting element substrate 103 is a line-of-sight direction, the groove 27A is formed outside the second color filter 20 (at a predetermined position in the outer area 10B). However, the groove 27A is formed at a position closer to the display area 10A than the proximal end 40A of the inclined portion 40 formed in the sealing substrate 22. The groove 27A may be formed in an annular shape similarly to the first embodiment or the like.

### (Protective Layer)

In the example of FIG. 16, the protective layer 16 has a multilayer structure in which a first protective layer 16A and a second protective layer 16B are laminated. The first protective layer 16A is formed in the display area 10A and the outer area 10B, and the position of the outer end surface 162 of the first protective layer 16A is a position outside the groove 27A (a position on the +X direction side of the groove 27A in FIG. 16). The position of the outer end surface 163 of the second protective layer 16B is a predetermined position (a position on the −X direction side in FIG. 16) closer to the display area 10A than the groove 27A. The outer end surface 163 of the second protective layer 16B is covered with the seal layer 29 described later.

### (Covering Layer)

The covering portion 160 of the protective layer 16 includes the first protective layer 16A. The covering portion 160 is in contact with the wall portion 127 and the bottom surface 128 of the groove 27A and covers the wall portion 127 and the bottom surface 128. In display device 10, a recessed structure which is the second height difference portion 134 is formed on an upper surface side (first surface side) of the covering portion 160, and the upper space 161 is formed inside the recessed structure.

### (Seal Layer)

A seal layer 29 is formed between the light emitting element substrate 103 and the sealing substrate 22 on the color filter 18. The seal layer 29 is preferably formed so as to cover substantially a region of the outer area 10B in a plan view of the light emitting element substrate 103. In the example of FIG. 16, the seal layer 29 is formed so as to cover the second planarizing layer 25. Furthermore, the seal layer 29 is formed so as to cover the first protective layer 16A in the outer area 10B, is formed so as to cover the upper surface side of the second height difference portion 134 formed in the covering portion 160 covering the groove 27A, and is formed so as to fill the upper space 161.

### (End Surface Coating Portion)

The end surface coating portion 42 covers the end surface 164 of the seal layer 29 and the outer end surface 162 of the first protective layer 16A.

In the display device 10 according to the tenth embodiment, the protective layer 16 is formed along the wall portion 127 and the bottom surface 128 of the groove 27A, and the area of the contact interface between the protective layer 16 and the inorganic insulating layer 12 increases. Therefore, it is possible to make it difficult for moisture to enter the display area 10A through the inside of the protective layer 16.

Furthermore, according to the display device 10 of the tenth embodiment, the upper space 161 is filled with the seal layer 29. Since the seal layer 29 often contains a material having excellent adhesion, the adhesion between the first protective layer 16A and the seal layer 29 is further enhanced. Furthermore, since the upper space 161 is filled with the seal layer 29, the area of the interface between the protective layer 16 and the seal layer 29 at the position of the covering portion 160 increases (the moisture entry path is extended). Therefore, moisture can be made less likely to enters the display area 10A along the interface between the protective layer 16 and the seal layer 29, and even if moisture enters from the interface between the protective layer and the seal layer, moisture can be made less likely to reach the display area along the interface.

### 11. Eleventh Embodiment

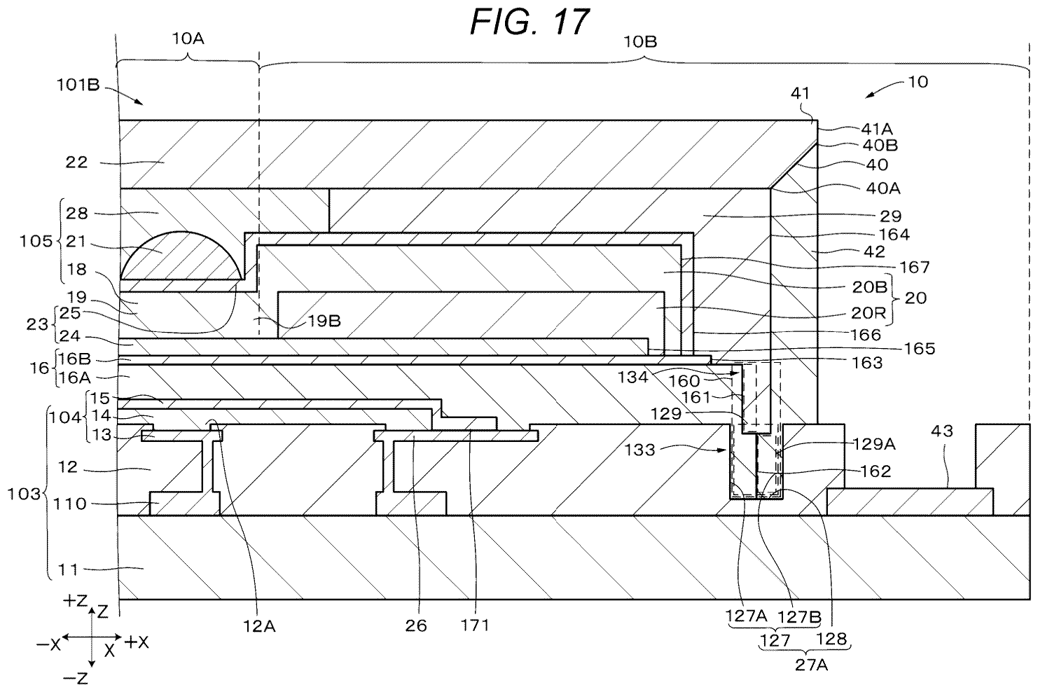

In a display device according to the eleventh embodiment, as illustrated in FIG. 17, a groove 27A is formed at a predetermined position outside the second color filter 20, and a part (portion 129A) of the groove 27A is filled with an end surface coating portion 42. FIG. 17 is a cross-sectional view schematically illustrating an example of the display device 10 according to the eleventh embodiment. An example of the display device 10 according to the eleventh embodiment illustrated in FIG. 17 is similar to the sixth embodiment except for the position of the groove 27A and a configuration in which a part of the groove 27A is filled with the end surface coating portion 42. Hereinafter, a description of the configuration similar to that of the sixth embodiment are redundant and thus will be omitted.

### (Groove or Step)

In the display device 10 according to the eleventh embodiment, a groove or a step is formed in the inorganic insulating layer 12. In the example of FIG. 17, a groove 27A is formed in the inorganic insulating layer 12. The groove 27A is formed outside the second color filter 20 in a case where the thickness direction of the light emitting element substrate 103 is a line-of-sight direction. Furthermore, in a case where the Z-axis direction is a line-of-sight direction, the proximal end 40A of the inclined portion 40 formed on the sealing substrate 22 is located on the bottom surface 128 of the groove 27A. The groove 27A may be formed in an annular shape similarly to the first embodiment and the like.

### (Protective Layer)

In the example of FIG. 17, the protective layer 16 has a multilayer structure in which a first protective layer 16A and a second protective layer 16B are laminated. The first protective layer 16A is formed in the display area 10A and the outer area 10B. In a case where the Z-axis direction is a line-of-sight direction, the position of the outer end surface 162 of the first protective layer 16A is the position in the bottom surface 128 of the groove 27A. The second protective layer is formed such that the position of an outer end surface 163 thereof is at a predetermined position on the display area 10A side with respect to the groove 27A. The outer end surface 163 of the second protective layer 16B is covered with the seal layer 29 described later.

### (Covering Portion)

The covering portion 160 of the protective layer 16 includes the first protective layer 16A. The covering portion 160 covers the wall portion 127 (first wall portion 127A) of the groove 27A and a part of the bottom surface 128. In the display device 10, a stepped structure is formed on the upper surface side (first surface side) of the covering portion 160, and the upper space 161 is formed at the position of the stepped structure.

### (Seal Layer)

A seal layer 29 is formed on the color filter 18. The seal layer 29 is preferably formed in a region covering the second planarizing layer 25 in plan view of the light emitting element substrate 103. In the example of FIG. 2, the seal layer 29 is formed so as to cover the second planarizing layer 25. Furthermore, the seal layer 29 is formed so as to fill the upper space 161 on the upper surface side of the covering portion 160 formed above the groove 27A.

### (End Surface Coating Portion)

The end surface coating portion 42 covers the end surface 164 of the seal layer 29 and the outer end surface 162 of the first protective layer 16A. Furthermore, the end surface coating portion 42 fills the groove 27A together with the first protective layer 16A (fills a part (portion 129A) of the in-groove space 129). The end surface coating portion 42 covers a part of the bottom surface 128 of the groove 27A and the second wall portion 127B and fills the portion 129A.

According to the display device 10 according to the eleventh embodiment, the first wall portion 127A and a part of the bottom surface 128 of the groove 27A are covered with the first protective layer 16A, and the moisture entry path when moisture enters the inside along the first protective layer 16A is extended. Furthermore, according to the display device 10 according to the eleventh embodiment, the outer end surface 162 of the first protective layer 16A is covered with the end surface coating portion 42. Since the end surface coating portion 42 often contains a material having excellent adhesion, the end surface coating portion 42 can effectively block moisture entry from the first protective layer 16A toward the display area 10A.

### 12. Example Cases where a Display Device has Resonator Structures

A case where resonator structures are formed in a display device 10 is now described, with the display device 10 according to the first embodiment being taken as an example. In the display device 10 according to the first embodiment, resonator structures may be further formed in at least some of the plurality of sub-pixels 101. Note that the resonator structures described in conjunction with the first embodiment may be applied in the second to eleventh embodiments.

### (Resonator Structures)

Resonator structures are formed in the display device 10. The resonator structures are cavity structures, and are structures that cause resonation of light generated in the organic layer 14. In the display device 10, the resonator structures are formed in the light emitting elements 104 (light emitting elements 104R, 104B, and 104G), and each resonator structure includes the first electrode 13, the organic layer 14, and the second electrode 15. Causing resonation of emitted light from the organic layer 14 means causing resonation of light of a specific wavelength included in the emitted light.

In a resonator structure, of the emitted light from the organic layer 14, the component that is reflected and resonates between predetermined layers such as between the first electrode 13 and the second electrode 15 is emphasized, and the light emphasized is emitted toward the outside from the side of the display surface D (first surface side).

The organic layer 14 generally uses light corresponding to the color type of the sub-pixel 101 as emitted light, and the resonator structure causes resonation of light of a specific wavelength included in the emitted light from the organic layer 14. At this point of time, light of a predetermined wavelength in the emitted light from the organic layer 14 is emphasized. Then, the light of the predetermined wavelength being emphasized, light is then emitted toward the outside from the side of the second electrode 15 (which is the light emitting surface side) of the light emitting element 104. Note that the light of the predetermined wavelength is light corresponding to a predetermined color type, and indicates light corresponding to a color type determined in accordance with the sub-pixel 101. The display device 10 includes the light emitting elements 104R, 104G, and 104B corresponding to the sub-pixels 101R, 101G, and 101B. Furthermore, a resonator structure is formed for each of the light emitting elements 104R, 104G, and 104B. In the resonator structure in the sub-pixel 101R, the red light of the emitted light from the organic layer 14 resonates. Light is emitted toward the outside from the second electrode 15 of the light emitting element 104R, with the red light being emphasized. Accordingly, red light having excellent color purity can be emitted from the sub-pixel 101R. In the resonator structures in the sub-pixels 101G and 101B, the green light and the blue light of the emitted light from the organic layer 14 resonate, respectively. In the sub-pixels 101G and 101B, light is emitted toward the outside from the second electrodes 15 of the light emitting elements 104G and 104B, with the green light and the blue light being emphasized. Accordingly, green light and blue light having excellent color purity can be emitted from the sub-pixels 101G and 101B, respectively.

As the resonator structures are formed in the display device 10 in this manner, the color purity of the sub-pixels 101 can be enhanced.

First to seventh examples will be sequentially described below as example cases where the display device has resonator structures, and the explanation will be continued.

### (Resonator Structure: First Example)

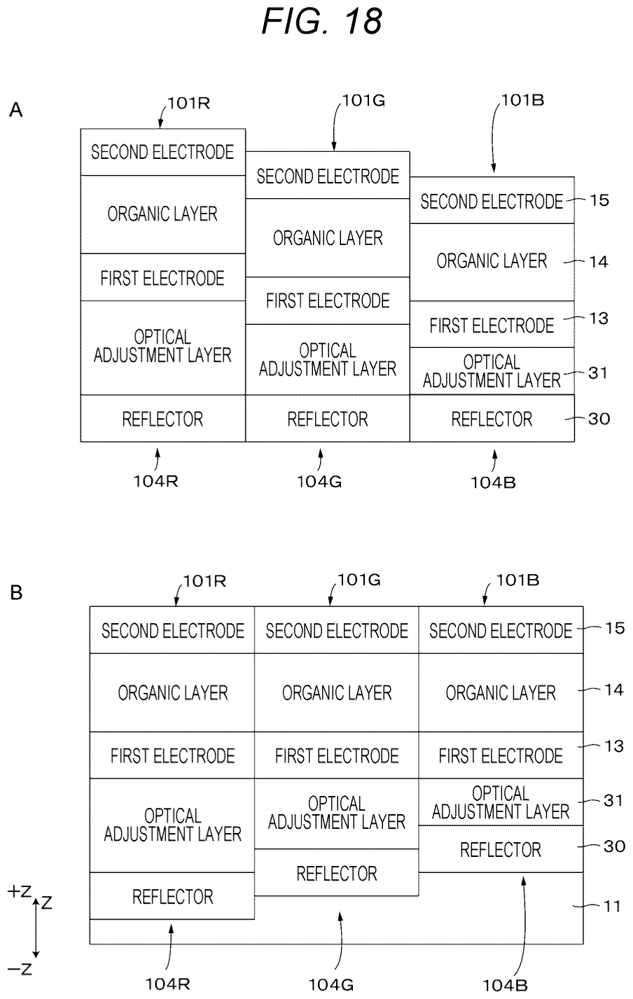

FIG. 18A is a schematic cross-sectional view for explaining a first example in a case where the display device 10 has a resonator structure.

In the first example, the thickness of the first electrode 13 and the thickness of the second electrode 15 are uniform among the sub-pixels 101R, 101G, and 101B.

In each of the sub-pixels 101R, 101G, and 101B (light emitting elements 104R, 104G, and 104B), an optical adjustment layer 31 is provided on the lower side (second surface side) of the first electrode 13, a reflector 30 is further disposed on the second surface side of the optical adjustment layer 31, and the optical adjustment layer 31 is formed between the reflector 30 and the first electrode 13. The resonator structure that causes resonation of light generated by the organic layer 14 is formed between the reflector 30 and the second electrode 15.

The thickness of the reflector 30 is the same among the sub-pixels 101R, 101G, and 101B. The thickness of the optical adjustment layer 31 varies among the sub-pixels 101R, 101G, and 101B. As the optical adjustment layer 31 has a thickness that varies among the sub-pixels 101R, 101G, and 101B, it is possible to set optical distances for causing resonance suitable for the sub-pixels 101R, 101G, and 101B.

In the example of FIG. 18A, the positions of the first surfaces of the reflectors 30 provided in the sub-pixels 101R, 101G, and 101B are arranged so as to be aligned in the up-down direction. In the sub-pixels 101R, 101G, and 101B, the positions of the first surfaces of the second electrodes 15 vary with the differences in the thickness among the optical adjustment layers 31.

The reflectors 30 can contain a metal such as aluminum (Al), silver (Ag), or copper (Cu), or an alloy containing these metals as principal components, for example.

The optical adjustment layers 31 can contain an inorganic insulating material such as silicon nitride (SiNx), silicon oxide (SiOx), or silicon oxynitride (SiOxNy), or an organic resin material such as an acrylic resin or a polyimide resin. Each optical adjustment layer 31 may be a single layer, or may be a film stack containing a plurality of materials.

Each second electrode 15 is preferably a layer that functions as a semi-transmissive reflective film. The second electrodes 15 can contain magnesium (Mg), silver (Ag), a magnesium-silver alloy (MgAg) containing these materials as the principal components, an alloy containing an alkali metal or an alkaline earth metal, or the like. The configurations of the first electrodes 13 and the organic layers 14 are similar to those described above, and therefore, explanation of them is not made herein.

### (Resonator Structure: Second Example)

FIG. 18B is a schematic cross-sectional view for explaining a second example in a case where the display device 10 has a resonator structure. The second example has a layer structure similar to that of the first example, except that the positions of the second electrodes 15 and the reflectors 30 are different from those in the first example.

In the sub-pixels 101R, 101G, and 101B (light emitting elements 104R, 104G, and 104B), the upper surfaces of the second electrodes 15 are arranged so that their positions in the vertical direction are aligned. The reflectors 30 provided in the sub-pixels 101R, 101G, and 101B are at different positions in the vertical direction, depending on the differences in thickness among the optical adjustment layers 31.

### (Resonator Structure: Third Example)

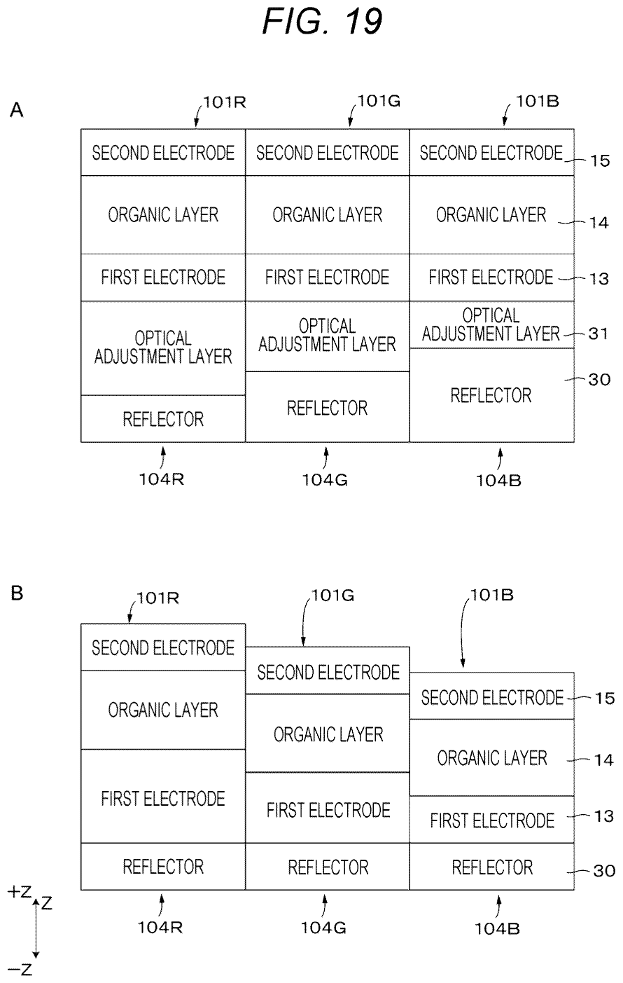

FIG. 19A is a schematic cross-sectional view for explaining a third example in a case where the display device 10 has a resonator structure. The third example has a layer structure similar to that of the first example, except that the thicknesses of the reflectors 30 vary among the sub-pixels 101R, 101G, and 101B (light emitting elements 104R, 104G, and 104B).

In the sub-pixels 101R, 101G, and 101B, the upper surfaces of the second electrodes 15 are arranged so that their positions in the vertical direction are aligned. The positions of the first surfaces of the reflectors 30 provided in the sub-pixels 101R, 101G, and 101B vary in the vertical direction, depending on the differences in thickness among the optical adjustment layers 31. However, the positions of the second surfaces of the reflectors 30 are aligned among the sub-pixels 101R, 101G, and 101B.

### (Resonator Structure: Fourth Example)

FIG. 19B is a schematic cross-sectional view for explaining a fourth example in a case where the display device 10 has a resonator structure. The fourth example is similar to the first example, except that the optical adjustment layers 31 are not included, and the thicknesses of the first electrodes 13 vary among the sub-pixels 101R, 101G, and 101B (light emitting elements 104R, 104G, and 104B).

Regarding the thicknesses of the first electrodes 13, the respective thicknesses of the first electrodes 13 are designed so as to set optical distances for causing optical resonance suitable for the sub-pixels 101R, 101G, and 101B.

### (Resonator Structure: Fifth Example)

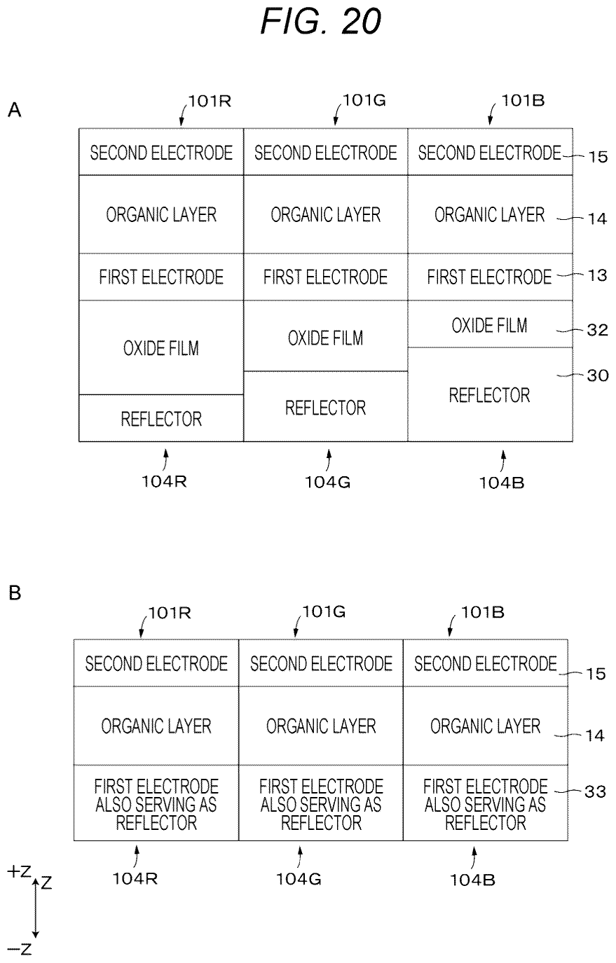

FIG. 20A is a schematic cross-sectional view for explaining a fifth example in a case where the display device 10 has a resonator structure. The fifth example is similar to the first example, except that the optical adjustment layers 31 are not included, and oxide films 32 are formed on the first surface side (the side of the surfaces facing the first electrodes 13) of the reflectors 30.

The thicknesses of the oxide films 32 vary among the sub-pixels 101R, 101G, and 101B (light emitting elements 104R, 104G, and 104B).

Regarding the thicknesses of the oxide films 32, the respective thicknesses of the oxide films 32 are designed so as to set optical distances for causing optical resonance suitable for the sub-pixels 101R, 101G, and 101B.

The oxide films 32 are films obtained by oxidizing the surfaces of the reflectors 30, and contain aluminum oxide, tantalum oxide, titanium oxide, magnesium oxide, zirconium oxide, or the like, for example. The oxide films 32 function as insulating films for adjusting the optical path lengths (optical distances) between the reflectors 30 and the second electrodes 15.

The oxide films 32 having thicknesses suitable for the sub-pixels 101R, 101G, and 101B can be formed in the following manner, for example.

First, a substrate on which the reflectors 30 are formed is immersed in a container filled with an electrolytic solution, and electrodes are disposed so as to face the reflectors 30.

Then, with the electrodes being used as references, positive voltages are then applied to the reflectors 30, to anodize the reflectors 30. Voltages corresponding to the thicknesses of the oxide films 32 to be obtained are applied to the reflectors 30 of the sub-pixels 101R, 101G, and 101B. As a result, the oxide films 32 having different thicknesses (the oxide films 32 having thicknesses suitable for the sub-pixels 101R, 101G, and 101B) can be collectively formed on the reflectors 30 of the sub-pixels 101R, 101G, and 101B.

### (Resonator Structure: Sixth Example)

FIG. 20B is a schematic cross-sectional view for explaining a sixth example in a case where the display device 10 has a resonator structure.

In the sixth example, each resonator structure of the display device 10 includes a structure in which the first electrode 13, the organic layer 14, and the second electrode 15 are laminated. In the sixth example, each first electrode 13 is a first electrode (also serving as a reflector) 33 that is designed to function as both an electrode and a reflector. The first electrodes (also serving as reflectors) 33 contain a material having an optical constant selected in accordance with the types of the light emitting elements 104R, 104G, and 104B. Since the phase shift by the first electrodes (also serving as reflectors) 33 vary, it is possible to set an optical distance for generating optimum resonance for the wavelength of light corresponding to the color to be displayed.

The first electrodes (also serving as reflectors) 33 can contain a single-component metal such as aluminum (Al), silver (Ag), gold (Au), or copper (Cu), or an alloy containing these metals as the principal components. For example, the first electrode (also serving as a reflector) 33R of the sub-pixel 101R may contain copper (Cu), and the first electrode (also serving as a reflector) 33G of the sub-pixel 101G and the first electrode (also serving as a reflector) 33B of the sub-pixel 101B may contain aluminum.

The second electrodes 15 and the organic layers 14 are similar to those of the first example, and therefore, explanation of them is not made herein.

### (Resonator Structure: Seventh Example)

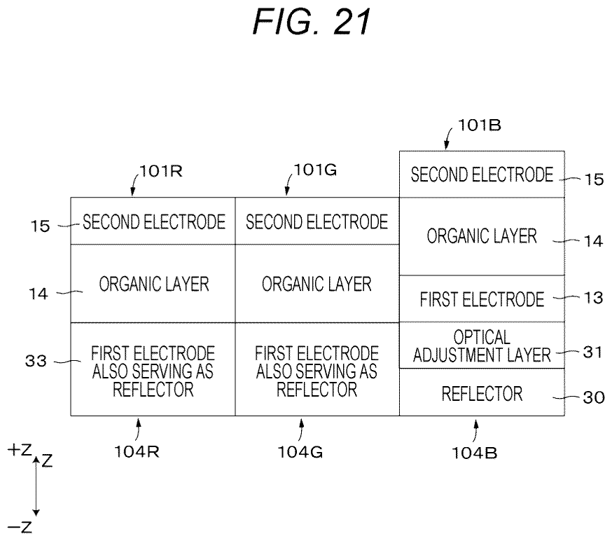

FIG. 21 is a schematic cross-sectional view for explaining a seventh example in a case where the display device 10 has a resonator structure.

In the seventh example, the resonator structures illustrated in the sixth example are provided for the sub-pixels 101R and 101G (light emitting elements 104R and 104G), and the resonator structure illustrated in the first example is provided for the sub-pixel 101B (light emitting element 104B).

[13 Examples of Positional Relationship in Cases where a Display Device Includes Wavelength Selection Units]

As a positional relationship in a case where wavelength selection units are formed in a display device 10, the mutual positional relationship among the light emitting units, the lens members, and the wavelength selection units is described, with the display device 10 according to the first embodiment being taken as an example. The display device 10 according to the first embodiment includes color filters as wavelength selection units. Note that [13 Example of positional relationship in cases where a display device includes wavelength selection units] may be applied to each embodiment (second to eleventh embodiments) including a color filter and a lens layer.

### (Color Filter, and Lens Layer)

In the display device 10 illustrated in the first embodiment, as illustrated in FIG. 1C, a wavelength selection unit and a lens member are provided on the first surface side of the planarizing layer 23 in each sub-pixel 101. In the example illustrated in the first embodiment, the wavelength selection unit is the color filter 18 (first color filter 19). For example, in the first embodiment, as the first color filters 19, a red filter 19R, a green filter 19G, and a blue filter 19B are provided for the sub-pixels 101R, 101G, and 101B, respectively. At this point of time, light absorbing layers are preferably provided between the adjacent first color filters 19. Examples of the light absorbing layers include black matrix portions. Furthermore, in the third embodiment, the second planarizing layer 25 is formed on the color filter 18. A lens 21 provided on the second planarizing layer 25 is provided as a lens member.

### (Relationship Among Normal Lines Extending Through the Centers of Light Emitting Units, Lens Members, and Wavelength Selection Units)

In the description below, the relationship among a normal line LN extending through the center of a light emitting unit, a normal line LN′ extending through the center of a lens member, and a normal line LN″ extending through the center of a wavelength selection unit is described. Here, the light emitting unit is, for example, a light emitting portion of the light emitting element 104. The lens member is the lens 21, for example. The wavelength selection unit is, for example, a red filter 19R, a green filter 19G, and a blue filter 19B.

Note that the size of the wavelength selection units may be changed as appropriate in accordance with light emitted from the light emitting units, or, in a case where the light absorbing units (black matrix portions, for example) are provided between the wavelength selection units of adjacent light emitting units, the size of the light absorbing units may be changed as appropriate in accordance with light emitted from the light emitting units. Furthermore, the size of each wavelength selection unit may be changed as appropriate in accordance with the distance (offset amount) do between the normal line extending through the center of the light emitting unit and the normal line extending through the center of the wavelength selection unit. The planar shape of each wavelength selection unit may be the same as, similar to, or different from the planar shape of each lens member.

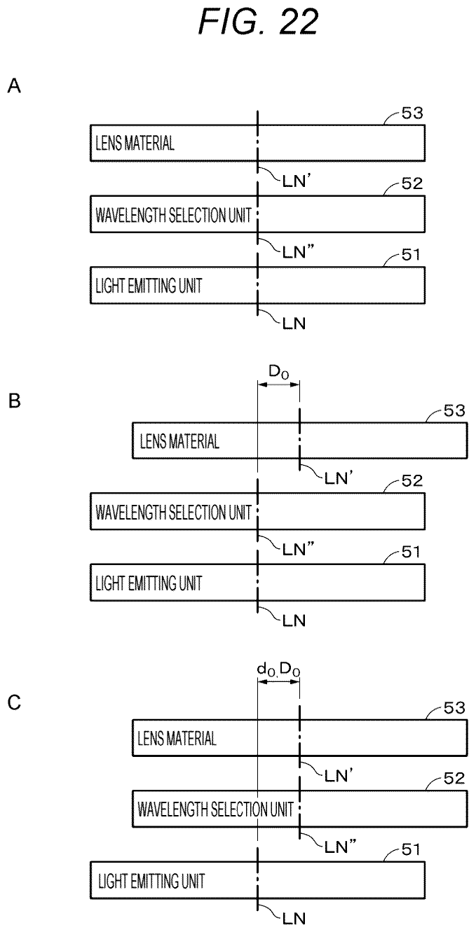

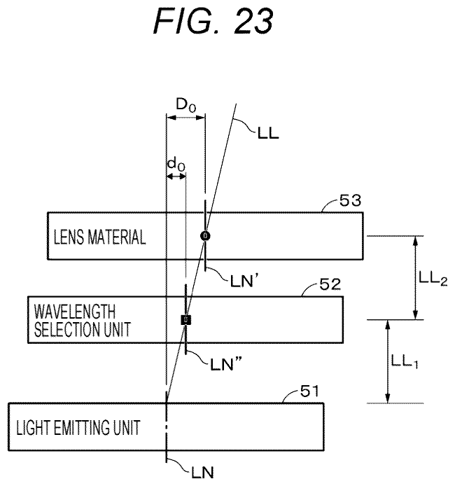

In the description below, referring to FIGS. 22A, 22B, 22C, and 23, the relationship among the normal lines extending through the center of the respective members in a case where a light emitting unit 51 (corresponding to the light emitting portion of the light emitting element 104 in the example in FIG. 2), a wavelength selection unit 52, and a lens member 53 are arranged in this order will be described.

As illustrated in FIG. 22A, a normal line LN passing through the center of the light emitting unit 51, a normal line LN″ passing through the center of the wavelength selection unit 52, and a normal line LN′ passing through the center of the lens member 53 may coincide with each other. That is, D₀=0 and d₀=0 may be satisfied. Here, Do represents the distance (offset amount) between the normal line LN extending through the center of the light emitting unit 51 and the normal line LN′ extending through the center of the lens member 53, and do represents the distance (offset amount) between the normal line LN extending through the center of the light emitting unit 51 and the normal line LN″ extending through the center of the wavelength selection unit 52.

As illustrated in FIG. 22B, the normal line LN extending through the center of the light emitting unit 51 and the normal line LN″ extending through the center of the wavelength selection unit 52 may coincide with each other, but the normal line LN extending through the center of the light emitting unit 51 and the normal line LN″ extending through the center of the wavelength selection unit 52 may not coincide with the normal line LN′ extending through the center of the lens member 53. That is, D₀>0 and d₀=0 may be satisfied.

As illustrated in FIG. 22C, the normal line LN extending through the center of the light emitting unit 51 may not coincide with the normal line LN″ extending through the center of the wavelength selection unit 52 and the normal line LN′ extending through the center of the lens member 53, and the normal line LN″ extending through the center of the wavelength selection unit 52 may coincide with the normal line LN′ extending through the center of the lens member 53. That is, D₀>0, d₀>0, and D₀=d₀ may be satisfied.

As illustrated in FIG. 23, the normal line LN passing through the center of the light emitting unit 51, the normal line LN″ passing through the center of the wavelength selection unit 52, and the normal line LN′ passing through the center of the lens member 53 may not coincide with each other. That is, D₀>0, d₀>0, and D₀+d₀ may be satisfied. Here, the center of the wavelength selection unit 52 (a position indicated by a black square in FIG. 23) is preferably located on a straight line LL connecting the center of the light emitting unit 51 and the center of the lens member 53 (a position indicated by a black circle in FIG. 23). Specifically, where the distance in the thickness direction (the vertical direction in FIG. 23) between the center of the light emitting unit 51 and the center of the wavelength selection unit 52 is represented by LL1, and the distance in the thickness direction between the center of the wavelength selection unit 52 and the center of the lens member 53 is represented by LL2, the following is preferably satisfied,

$${D}_{0} > {d}_{0} > 0$$

and, with manufacturing variations being taken into consideration, the following is preferably satisfied,

$${d}_{0} : {D}_{0} = {LL}_{1} : ( {LL}_{1} + {LL}_{2} )$$

Here, the thickness direction indicates the thickness direction of the light emitting unit 51, the wavelength selection unit 52, and the lens member 53.

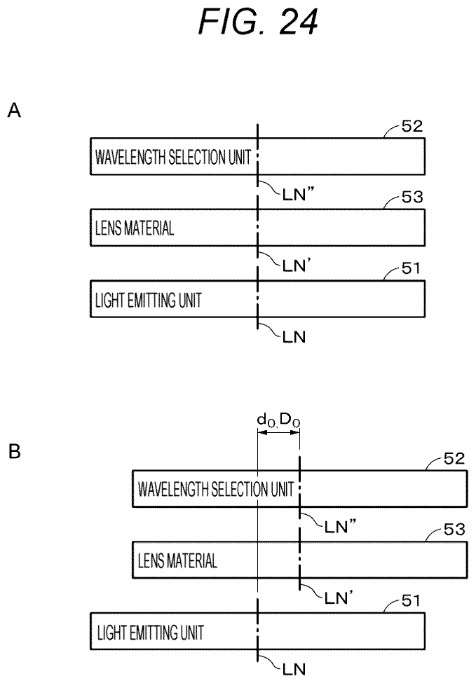

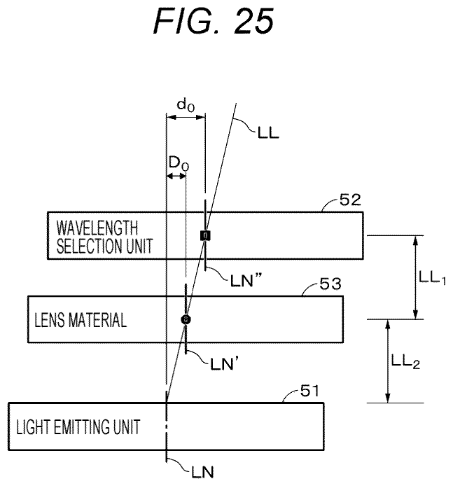

Hereinafter, with reference to FIGS. 24A, 24B, and 25, a relationship of a normal line passing through the center of each part in a case where the light emitting unit 51, the lens member 53, and the wavelength selection unit 52 are disposed in this order will be described.

As illustrated in FIG. 24A, a normal line LN passing through the center of the light emitting unit 51, a normal line LN″ passing through the center of the wavelength selection unit 52, and a normal line LN′ passing through the center of the lens member 53 may coincide with each other. That is, D₀>0 and d₀=0 may be satisfied.

As illustrated in FIG. 24B, a normal line LN passing through the center of the light emitting unit 51, a normal line LN″ passing through the center of the wavelength selection unit 52 and the normal line LN′ passing through the center of the lens member 53 do not coincide with each other, and the normal line LN″ passing through the center of the wavelength selection unit 52, and a normal line LN′ passing through the center of the lens member 53 may coincide with each other. That is, D₀>0, d₀>0, and D₀=d₀ may be satisfied.

As illustrated in FIG. 25, the normal line LN passing through the center of the light emitting unit 51, the normal line LN″ passing through the center of the wavelength selection unit 52, and the normal line LN′ passing through the center of the lens member 53 may not coincide with each other. Here, the center of the lens member 53 (the position indicated by a black circle in FIG. 25) is preferably located on the straight line LL connecting the center of the light emitting unit 51 and the center of the wavelength selection unit 52 (the position indicated by a black square in FIG. 25). Specifically, where the distance in the thickness direction (the vertical direction in FIG. 25) between the center of the light emitting unit 51 and the center of the lens member 53 is represented by LL2, and the distance in the thickness direction between the center of the lens member 53 and the center of the wavelength selection unit 52 is represented by LL1, the following expression is preferably satisfied,

$${d}_{0} > {D}_{0} > 0$$

and, with manufacturing variations being taken into consideration, the following expression is preferably satisfied,

$${D}_{0} : {d}_{0} = {LL}_{2} : ( {LL}_{1} + {LL}_{2} )$$

Here, the thickness direction indicates the thickness direction of the light emitting unit 51, the wavelength selection unit 52, and the lens member 53.

### [14 Application Example]

### (Electronic Apparatus)

A display device 10 according to the above-described embodiment may be provided in various electronic apparatuses. Especially, the display device is preferably provided in an apparatus requiring high resolution of an image and used near the eyes for viewing in a magnified state, the apparatus including an electronic viewfinder of a video camera or a single-lens reflex camera, a head mounted display, or the like. The display device 10 according to the above-described embodiment includes all of the display devices described in the first to eleventh embodiments and the modifications, the display device in the case of having the resonator structure, and the display device described in the example of the positional relationship in the case of having the wavelength selection unit.

### (Specific Example 1)

FIG. 26A is a front view illustrating an example of an external appearance of a digital still camera 310. FIG. 26B is a rear view illustrating an example of an external appearance of the digital still camera 310. The digital still camera 310 is of a lens interchangeable single-lens reflex type, and includes an interchangeable imaging lens unit (interchangeable lens) 312 substantially at the center on the front surface of a camera main body (camera body) 311, and a grip 313 to be held by the photographer on the front left side.

A monitor 314 is provided at a position shifted to the left side from the center of the rear surface of the camera main body 311. An electronic viewfinder (eyepiece window) 315 is provided above the monitor 314. By looking through the electronic viewfinder 315, the photographer can visually recognize an optical image of the subject guided from the imaging lens unit 312, and determine a picture composition. As the electronic viewfinder 315, a display device 10 according to any one of the above embodiments can be used.

### (Specific Example 2)

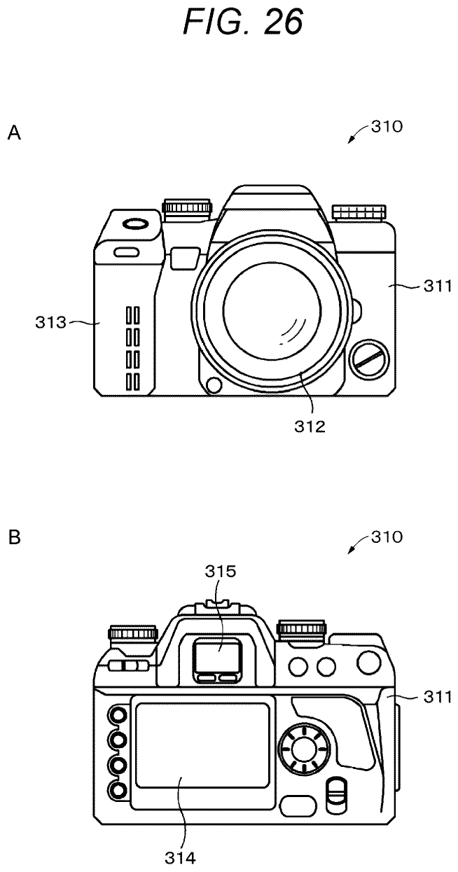

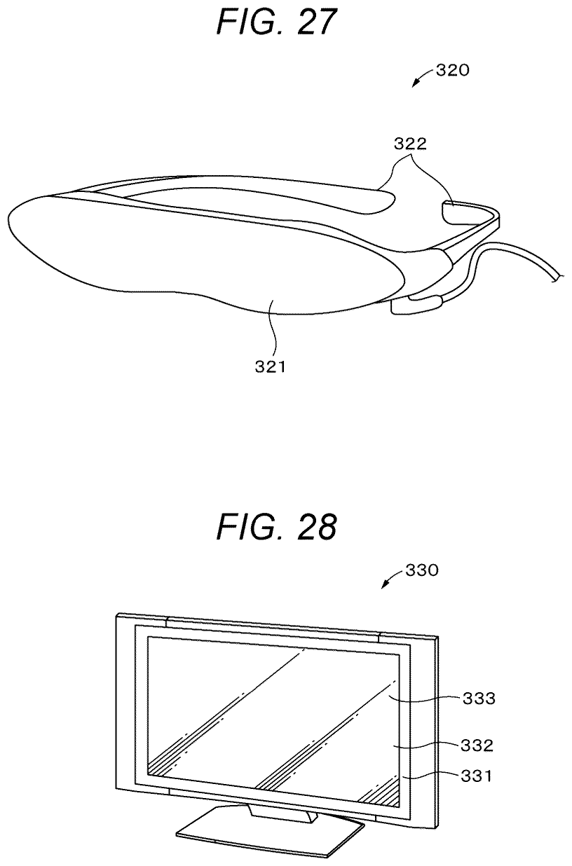

FIG. 27 is a perspective view illustrating an example of an external appearance of a head-mounted display 320. The head-mounted display 320 includes ear hooking portions 322 to be worn on the head of the user on both sides of a display unit 321 in the shape of eyeglasses, for example. As the display unit 321, a display device 10 according to any one of the above embodiments and modifications thereof can be used.

### (Specific Example 3)

FIG. 28 is a perspective view illustrating an example of an external appearance of a television device 330. The television device 330 includes a video display screen unit 331 including a front panel 332 and a filter glass 333, and the video display screen unit 331 includes a display device 10 according to any one of the above embodiments and modifications thereof, for example.

### (Specific Example 4)

FIG. 29 illustrates an example of an external appearance of a see-through head-mounted display 340. The see-through head-mounted display 340 includes a main body 341, an arm 342, and a lens barrel 343.

The main body 341 is connected to the arm 342 and eyeglasses 350. Specifically, an end portion of the main body 341 in the long side direction is coupled to the arm 342, and one side of a side surface of the main body 341 is coupled to the eyeglasses 350 via a connecting member. Note that the main body 341 may be directly mounted on the head of the human body.

The main body 341 incorporates a control board for controlling operation of the see-through head-mounted display 340, and a display unit. The arm 342 connects the main body 341 and the lens barrel 343, and supports the lens barrel 343. Specifically, the arm 342 is coupled to an end portion of the main body 341 and an end portion of the lens barrel 343, and secures the lens barrel 343. Furthermore, the arm 342 incorporates a signal line for communicating data related to an image to be provided from the main body 341 to the lens barrel 343.

The lens barrel 343 projects image light provided from the main body 341 via the arm 342 toward the eyes of the user wearing the see-through head-mounted display 340 through an eyepiece 351. In this see-through head-mounted display 340, the display unit of the main body 341 includes any one of the above display devices 10 and the like.

### (Specific Example 5)

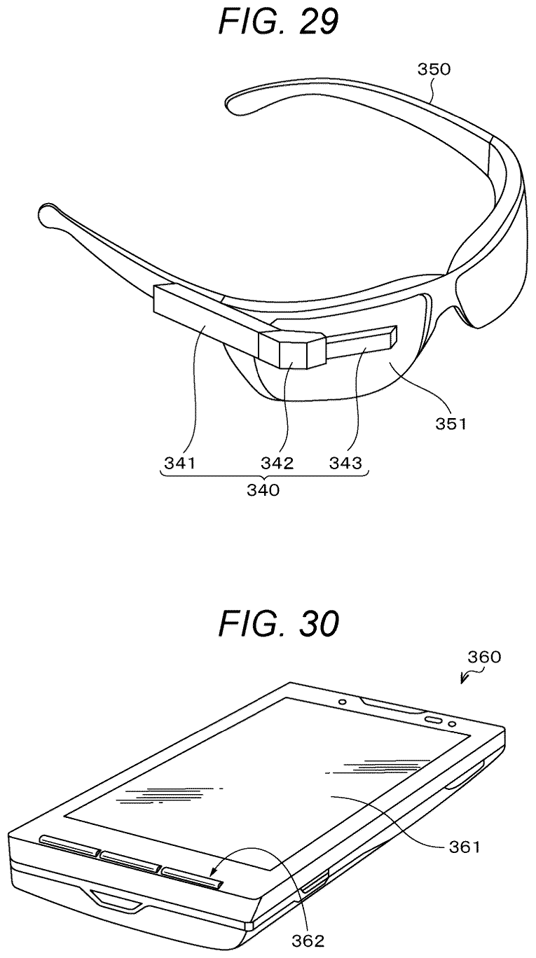

FIG. 30 is a perspective view illustrating an example of an external appearance of a smartphone 360. As illustrated in FIG. 33, the smartphone 360 includes a display unit 361 that displays information about pixels or the like, an operating unit 362 that includes buttons and the like for receiving an operation input by the user. A display device 10 according to the above embodiments and modifications can be adopted as the display unit 361.

### (Specific Example 6)

Any of the display devices 10 and the like described above may be included in a vehicle or in various kinds of displays.

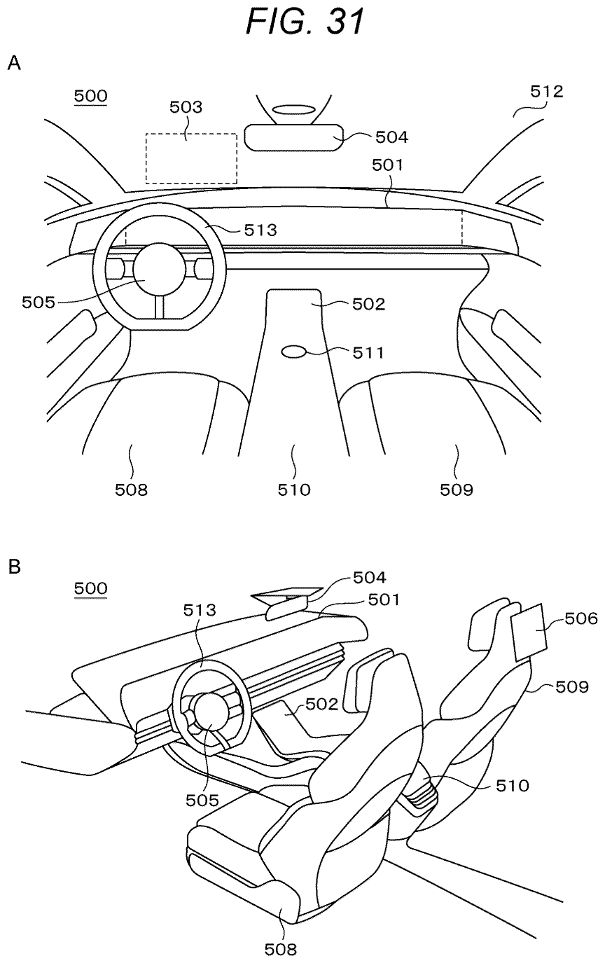

FIGS. 31A and 31B are diagrams illustrating an example of an internal configuration of a vehicle 500 provided with various displays. Specifically, FIG. 31A is a diagram illustrating an example of an internal state of the vehicle 500 as viewed from the rear side to the front side of the vehicle 500. FIG. 31B is a diagram illustrating an example of an internal state of the vehicle 500 as viewed obliquely from the rear side to the front side of the vehicle 500.

The vehicle 500 includes a center display 501, a console display 502, a head-up display 503, a digital rearview mirror 504, a steering wheel display 505, and a rear entertainment display 506. At least one of these displays includes any one of the above display devices 10 and the like. For example, all of these displays may include one of the above display devices 10 and the like.

The center display 501 is disposed on the dashboard at a location facing a driver's seat 508 and a passenger seat 509. FIGS. 31A and 31B illustrate an example of the center display 501 having a horizontally long shape extending from the side of the driver's seat 508 to the side of the passenger seat 509, but any screen size and installation location for the center display 501 may be adopted. The center display 501 can display information sensed by various sensors. As a specific example, the center display 501 can display an image captured by an image sensor, an image of the distance to an obstacle in front of or on a side of the vehicle 500, the distance being measured by a ToF sensor, a passenger's body temperature detected by an infrared sensor, and the like. The center display 501 can be used to display at least one piece of safety-related information, operation-related information, lifelogs, health-related information, authentication/identification-related information, or entertainment-related information, for example.

The safety-related information is information about doze sensing, looking-away sensing, sensing of mischief of a child riding together, presence or absence of wearing of a seat belt, sensing of leaving of an occupant, and the like, and is information sensed by a sensor disposed to overlap with the back surface side of the center display 501, for example. The operation-related information senses a gesture related to an operation performed by an occupant, using a sensor. Gestures to be sensed may include an operation of various kinds of equipment in the vehicle 500. For example, operations of air conditioning equipment, a navigation device, an audiovisual (AV) device, an illuminating device, and the like are detected. The lifelogs include lifelogs of all the occupants. For example, the lifelogs include an action record of each occupant in the vehicle. By acquiring and storing the lifelogs, it is possible to check the state of each occupant at the time of an accident. The health-related information senses the body temperature of an occupant, using a sensor such as a temperature sensor, and estimates the health condition of the occupant on the basis of the sensed body temperature. Alternatively, the face of the occupant may be imaged with an image sensor, and the health condition of the occupant may be estimated from the imaged facial expression. Moreover, a conversation may be made with an occupant in automatic voice, and the health condition of the occupant may be estimated on the basis of the contents of a response from the occupant. The authentication/identification-related information includes a keyless entry function of performing face authentication using a sensor, and a function of automatically adjusting a seat height and position through face identification. The entertainment-related information includes a function of detecting, with a sensor, operation information about an AV device being used by an occupant, and a function of recognizing the face of the occupant with sensor and providing content suitable for the occupant through the AV device.

The console display 502 can be used to display lifelog information, for example. The console display 502 is disposed near a shift lever 511 of a center console 510 between the driver's seat 508 and the passenger seat 509. The console display 502 can also display information detected by various sensors. Furthermore, the console display 502 may display an image of the surroundings of the vehicle captured with an image sensor, or may display an image of the distance to an obstacle present in the surroundings of the vehicle.

The head-up display 503 is virtually displayed behind a windshield 512 in front of the driver's seat 508. The head-up display 503 can be used to display at least one piece of the safety-related information, the operation-related information, the lifelogs, the health-related information, the authentication/identification-related information, or the entertainment-related information, for example. Being virtually disposed in front of the driver's seat 508 in many cases, the head-up display 503 is suitable for displaying information directly related to operations of the vehicle 500, such as the speed, the remaining amount of fuel (battery), and the like of the vehicle 500.

The digital rearview mirror 504 can not only display the rear of the vehicle 500 but also display the state of an occupant in the rear seat, and thus, can be used to display the lifelog information by disposing a sensor on the back surface side of the digital rearview mirror 504 in an overlapping manner, for example.

The steering wheel display 505 is disposed near the center of a steering wheel 513 of the vehicle 500. The steering wheel display 505 can be used to display at least one piece of the safety-related information, the operation-related information, the lifelogs, the health-related information, the authentication/identification-related information, or the entertainment-related information, for example. In particular, being located close to the driver's hands, the steering wheel display 505 is suitable for displaying the lifelog information such as the body temperature of the driver, or for displaying information regarding operations of the AV device, the air conditioning equipment, or the like.

The rear entertainment display 506 is attached to the back side of the driver's seat 508 or the passenger seat 509, and is for an occupant in the rear seat to enjoy viewing/listening. The rear entertainment display 506 can be used to display at least one piece of the safety-related information, the operation-related information, the lifelogs, the health-related information, the authentication/identification-related information, or the entertainment-related information, for example. In particular, as the rear entertainment display 506 is located in front of an occupant in the rear seat, information related to the occupant in the rear seat is displayed. For example, information regarding an operation of the AV device or the air conditioning equipment may be displayed, or a result of measurement of the body temperature or the like of an occupant in the rear seat with a temperature sensor may be displayed.

A sensor may be disposed on the back surface side of a display device 10 or the like in an overlapping manner, so that the distance to an object present in the surroundings can be measured in the configuration. Optical distance measurement methods are roughly classified into a passive type and an active type. By a method of the passive type, distance measurement is performed by receiving light from an object, without projecting light from a sensor to the object. Methods of the passive type include a lens focus method, a stereo method, and a monocular vision method. Methods of the active type include distance measurement that is performed by projecting light onto an object, and receiving reflected light from the object with a sensor to measure the distance. Methods of the active type include an optical radar method, an active stereo method, an illuminance difference stereo method, a moire topography method, and an interference method. Any of the display devices 10 and the like described above can be used in distance measurement by any of these methods. With a sensor disposed on the back surface side of the above display device 10 or the like in an overlapping manner, distance measurement of the passive type or the active type described above can be performed.

Although the display devices and the application examples according to the first to eleventh embodiments and each modification of the present disclosure have been specifically described above, the present disclosure is not limited to the display devices and the application examples according to the first to seventh embodiments and each modification described above, and various modifications based on the technical idea of the present disclosure are possible.

For example, the configurations, methods, steps, shapes, materials, numerical values, and the like given in the display devices and the application examples according to the first to eleventh embodiments and each modification described above are merely examples, and different configurations, methods, steps, shapes, materials, numerical values, and the like may be used as necessary.

The configurations, methods, steps, shapes, materials, numerical values, and the like of the display devices and the application examples according to the first to eleventh embodiments and each modification described above can be combined with each other without departing from the gist of the present disclosure.

The materials exemplified in the display devices and the application examples according to the first to eleventh embodiments and each modification described above can be used alone or in combination of two or more unless otherwise specified.

Furthermore, the present disclosure can also adopt the following configurations.

(1)

A display device including:
a light emitting element substrate in which an inorganic insulating layer and a light emitting element are formed in this order on a substrate; and
a protective layer that covers an upper surface side of the light emitting element substrate, in which
the protective layer is provided with a planarizing layer and a functional layer different from the planarizing layer on an upper side of the protective layer,
the inorganic insulating layer has at least one of a groove or a step, and
the protective layer includes a covering portion that covers at least a part of the groove or the step.
   (2)

The display device according to (1), including: a display area defined as a region where light generated by the light emitting element is emitted; and an outer area defined as a region outside an outer peripheral edge of the display area, in which
the inorganic insulating layer has the groove or the step at a position corresponding to the outer area.
   (3)

The display device according to (1) or (2), in which
at least a part of the groove or the step is formed below the planarizing layer or the functional layer.
   (4)

The display device according to any one of (1) to (3), further including:
a sealing substrate, in which
the planarizing layer and the functional layer are formed between the protective layer and the sealing substrate, and
the groove or the step is formed at a lower position of an end portion of the sealing substrate or a position closer to the display area side than the lower position.
   (5)

The display device according to any one of (1) to (4), in which
the functional layer includes a color filter,
the color filter includes a first color filter to which light generated in the light emitting element is incident and a second color filter formed outside the first color filter, and
the groove or the step is provided at a lower position of the second color filter.
   (6)

The display device according to (5), in which
the second color filter has a light shielding property.
   (7)

The display device according to any one of (1) to (6), in which
the light emitting element has a structure in which a first electrode, an organic compound layer, and a second electrode are laminated in this order,
the display device includes an auxiliary electrode provided in the outer area and electrically connected to the second electrode, and
the groove or the step is provided in a formation region of the auxiliary electrode.
   (8)

The display device according to any one of (1) to (7), in which
the light emitting element has a structure in which a first electrode, an organic compound layer, and a second electrode are laminated in this order,
the display device includes an auxiliary electrode provided in the outer area and electrically connected to the second electrode, and
the groove or the step is provided at a position closer to the display area side than a formation region of the auxiliary electrode.
   (9)

The display device according to any one of (1) to (8), in which
a connection terminal electrically connected to an external device is provided in the outer area and outside the groove or the step.
   (10)

The display device according to any one of (1) to (9), in which
an upper portion of the groove or the step is covered with the planarizing layer.
   (11)

The display device according to any one of (1) to (10), in which
a recessed structure is formed on an upper surface side of the covering portion, and
an upper portion of the recessed structure is covered with the planarizing layer.
   (12)

The display device according to any one of (1) to (11), in which
the planarizing layer includes a hygroscopic member.
   (13)

The display device according to any one of (1) to (12), in which
the planarizing layer includes a lower planarizing layer and an upper planarizing layer,
the lower planarizing layer is provided in the outer area,
the upper planarizing layer is provided at least in the display area and covers the lower planarizing layer, and
the groove or the step is provided below the lower planarizing layer.
   (14)

The display device according to (13), in which
the lower planarizing layer includes a hygroscopic member.
   (15)

The display device according to any one of (1) to (14), in which
the protective layer has a structure in which an inorganic layer and an organic layer are laminated.
   (16)

The display device according to any one of (1) to (15), further including:
a sealing substrate, in which the functional layer includes a seal layer,
the seal layer is formed between the light emitting element substrate and the sealing substrate and in the outer area,
a recessed structure is formed on an upper surface side of the covering portion, and
an upper portion of the recessed structure is covered with the seal layer.
   (17)

An electronic apparatus including:
a display device according to any one of (1) to (16).

### REFERENCE SIGNS LIST

1 Display panel
10 Display device
10A Display area
10B Outer area
11 Substrate
12 Inorganic insulating layer
12A Opening
13 First electrode
14 Organic layer
15 Second electrode
16 Protective layer
16A First protective layer
16B Second protective layer
18 Color filter
19 First color filter
20 Second color filter
21 Lens
22 Sealing substrate
23 Planarizing layer
26 Auxiliary electrode
27A Groove
27B Step
28 Filling layer
29 Seal layer
40 Inclined portion
40A Proximal end
40B Distal end
42 End surface coating portion
43 Connection terminal
101 Sub-pixel
103 Light emitting element substrate
104 Light emitting element
105 Functional layer
110 Wiring
127 Wall portion
127A First wall portion
127B Second wall portion
128 Bottom surface
129 In-groove space
130 Wall portion
131 Bottom surface
160 Covering portion
161 Upper space
170 Cavity portion
171 Connecting part

1. A display device comprising:
a light emitting element substrate in which an inorganic insulating layer and a light emitting element are formed in this order on a substrate; and
a protective layer that covers an upper surface side of the light emitting element substrate, wherein
the protective layer is provided with a planarizing layer and a functional layer different from the planarizing layer on an upper side of the protective layer,
the inorganic insulating layer has at least one of a groove or a step, and
the protective layer includes a covering portion that covers at least a part of the groove or the step.

2. The display device according to claim 1, further comprising: a display area defined as a region where light generated by the light emitting element is emitted; and an outer area defined as a region outside an outer peripheral edge of the display area, wherein
the inorganic insulating layer has the groove or the step at a position corresponding to the outer area.

3. The display device according to claim 2, wherein
at least a part of the groove or the step is formed below the planarizing layer or the functional layer.

4. The display device according to claim 2, further comprising:
a sealing substrate, wherein
the planarizing layer and the functional layer are formed between the protective layer and the sealing substrate, and
the groove or the step is formed at a lower position of an end portion of the sealing substrate or a position closer to the display area side than the lower position.

5. The display device according to claim 2, wherein
the functional layer includes a color filter,
the color filter includes a first color filter to which light generated in the light emitting element is incident and a second color filter formed outside the first color filter, and
the groove or the step is provided at a lower position of the second color filter.

6. The display device according to claim 5, wherein
the second color filter has a light shielding property.

7. The display device according to claim 2, wherein
the light emitting element has a structure in which a first electrode, an organic compound layer, and a second electrode are laminated in this order,
the display device further comprises an auxiliary electrode provided in the outer area and electrically connected to the second electrode, and
the groove or the step is provided in a formation region of the auxiliary electrode.

8. The display device according to claim 2, wherein
the light emitting element has a structure in which a first electrode, an organic compound layer, and a second electrode are laminated in this order,
the display device further comprises an auxiliary electrode provided in the outer area and electrically connected to the second electrode, and
the groove or the step is provided at a position closer to the display area side than a formation region of the auxiliary electrode.

9. The display device according to claim 2, wherein
a connection terminal electrically connected to an external device is provided in the outer area and outside the groove or the step.

10. The display device according to claim 2, wherein
an upper portion of the groove or the step is covered with the planarizing layer.

11. The display device according to claim 2, wherein
a recessed structure is formed on an upper surface side of the covering portion, and
an upper portion of the recessed structure is covered with the planarizing layer.

12. The display device according to claim 2, wherein
the planarizing layer includes a hygroscopic member.

13. The display device according to claim 2, wherein
the planarizing layer includes a lower planarizing layer and an upper planarizing layer,
the lower planarizing layer is provided in the outer area,
the upper planarizing layer is provided at least in the display area and covers the lower planarizing layer, and
the groove or the step is provided below the lower planarizing layer.

14. The display device according to claim 13, wherein
the lower planarizing layer includes a hygroscopic member.

15. The display device according to claim 2, wherein
the protective layer has a structure in which an inorganic layer and an organic layer are laminated.

16. The display device according to claim 2, further comprising:
a sealing substrate, wherein
the functional layer includes a seal layer,
the seal layer is formed between the light emitting element substrate and the sealing substrate and in the outer area,
a recessed structure is formed on an upper surface side of the covering portion, and
an upper portion of the recessed structure is covered with the seal layer.

17. An electronic apparatus comprising:
a display device according to claim 1.
